(19) United States
(12) Patent Application Publication
(10) Pub. No.: US 2025/0107259 A1
(43) Pub. Date: Mar. 27, 2025

(54) IMAGING DEVICE AND ELECTRONIC DEVICE

(71) Applicant: SONY SEMICONDUCTOR SOLUTIONS CORPORATION, KANAGAWA (JP)

(72) Inventors: NAOYUKI SATO, KANAGAWA (JP); YASUFUMI MIYOSHI, KANAGAWA (JP); KEIJI OHSHIMA, KANAGAWA (JP); MASANAGA FUKASAWA, KANAGAWA (JP)

(21) Appl. No.: 18/729,997

(22) PCT Filed: Jan. 19, 2023
(86) PCT No.: PCT/JP2023/001543

§ 371 Date: Jul. 18, 2024

(30) Foreign Application Priority Data
Jan. 26, 2022 (JP) 2022-010191

(51) Int. Cl. H01L 27/146

(52) U.S. Cl. CPC H10F 39/807; H10F 39/011; H10F 39/182

(57) ABSTRACT

There is provided an imaging device including a semiconductor substrate (300), and a plurality of imaging elements (100) that is arrayed in a matrix on the semiconductor substrate and that performs photoelectric conversion on incident light, in which each of the plurality of imaging elements includes a plurality of pixels (302a and 302b) which is provided in such a manner as to be adjacent to each other in a predetermined unit region of the semiconductor substrate and each of which includes a photoelectric conversion unit, and a pixel isolation portion (304) that isolates the plurality of pixels, the pixel isolation portion is provided in such a manner as to penetrate at least a part of the semiconductor substrate in a thickness direction of the semiconductor substrate, and at least one of surfaces of the pixel isolation portion is an uneven surface.

### FIELD

The present disclosure relates to an imaging device and an electronic device.

### BACKGROUND

In order to further improve an autofocus function while avoiding deterioration of a captured image, it is proposed to provide phase difference detection pixels on an entire surface of a pixel array unit of an imaging device. In such a pixel, a pair of pixels is provided for phase difference detection, and a pixel isolation portion is further provided to optically and electrically isolate the pair of pixels.

### CITATION LIST

### Patent Literature

Patent Literature 1: US 2018/0219040 A
Patent Literature 2: US 2019/0296070 A

### SUMMARY

### Technical Problem

However, there is a case where light incident on a pixel is reflected by the pixel isolation portion described above and accuracy (isolation ratio) of phase difference detection is deteriorated or color mixture is generated.

Thus, the present disclosure proposes an imaging device and an electronic device capable of reducing reflection and controlling deterioration in accuracy of phase difference detection and generation of color mixture between adjacent imaging elements.

### Solution to Problem

According to the present disclosure, there is provided an imaging device including: a semiconductor substrate; and a plurality of imaging elements that is arrayed in a matrix on the semiconductor substrate and that performs photoelectric conversion on incident light. In the imaging device, each of the plurality of imaging elements includes a plurality of pixels which is provided in such a manner as to be adjacent to each other in a predetermined unit region of the semiconductor substrate and each of which includes a photoelectric conversion unit, and a pixel isolation portion that isolates the plurality of pixels, the pixel isolation portion is provided in such a manner as to penetrate at least a part of the semiconductor substrate in a thickness direction of the semiconductor substrate, and at least one of surfaces of the pixel isolation portion is an uneven surface.

Furthermore, according to the present disclosure, there is provided an electronic device including an imaging device. The imaging device includes: a semiconductor substrate, and a plurality of imaging elements that is arrayed in a matrix on the semiconductor substrate and that performs photoelectric conversion on incident light. In the imaging device, each of the plurality of imaging elements includes a plurality of pixels which is provided in such a manner as to be adjacent to each other in a predetermined unit region of the semiconductor substrate and each of which includes a photoelectric conversion unit, and a pixel isolation portion that isolates the plurality of pixels, the pixel isolation portion is provided in such a manner as to penetrate at least a part of the semiconductor substrate in a thickness direction of the semiconductor substrate, and at least one of surfaces of the pixel isolation portion is an uneven surface.

### BRIEF DESCRIPTION OF DRAWINGS

FIG. 1 is an explanatory diagram illustrating a plane configuration example of an imaging device 1 according to an embodiment of the present disclosure.

FIG. 2 is a schematic diagram of a cross section of an imaging element 100a according to a comparative example.

FIG. 3 is a schematic diagram (part 1) of a cross section of an imaging element 100 according to a first embodiment of the present disclosure.

FIG. 4 is a schematic diagram (part 2) of a cross section of the imaging element 100 according to the first embodiment of the present disclosure.

FIG. 5 is a cross-sectional view for describing a part of a manufacturing process of a manufacturing method of the imaging element 100 according to the first embodiment of the present disclosure.

FIG. 6 is a schematic diagram of a cross section of an imaging element 100 according to a first modification example of the first embodiment of the present disclosure.

FIG. 7 is a cross-sectional view for describing a part of a manufacturing process of a manufacturing method of the imaging element 100 according to the first modification example of the first embodiment of the present disclosure.

FIG. 8 is a schematic diagram (part 1) of a cross section of an imaging element 100 according to a second modification example of the first embodiment of the present disclosure.

FIG. 9 is a schematic diagram (part 2) of a cross section of the imaging element 100 according to the second modification example of the first embodiment of the present disclosure.

FIG. 10 is a schematic diagram (part 3) of the cross section of the imaging element 100 according to the second modification example of the first embodiment of the present disclosure.

FIG. 11 is an explanatory diagram (part 1) for describing a second embodiment of the present disclosure.

FIG. 12 is an explanatory diagram (part 2) for describing the second embodiment of the present disclosure.

FIG. 13 is a schematic diagram of a cross section of an imaging element 100 according to the second embodiment of the present disclosure.

FIG. 14 is a schematic diagram of a cross section of an imaging element 100 according to a modification example of the second embodiment of the present disclosure.

FIG. 15 is a schematic diagram (part 1) of a cross section of an imaging element 100 according to a third embodiment of the present disclosure.

FIG. 16 is a schematic diagram (part 2) of a cross section of the imaging element 100 according to the third embodiment of the present disclosure.

FIG. 17 is a schematic diagram (part 3) of the cross section of the imaging element 100 according to the third embodiment of the present disclosure.

FIG. 18 is a schematic diagram (part 4) of the cross section of the imaging element 100 according to the third embodiment of the present disclosure.

FIG. 19 is a schematic diagram (part 1) of a cross section of an imaging element 100 according to a first modification example of the third embodiment of the present disclosure.

FIG. 20 is a schematic diagram (part 2) of a cross section of the imaging element 100 according to the first modification example of the third embodiment of the present disclosure.

FIG. 21 is a schematic diagram (part 1) of a cross section of an imaging element 100 according to a second modification example of the third embodiment of the present disclosure.

FIG. 22 is a schematic diagram (part 2) of a cross section of the imaging element 100 according to the second modification example of the third embodiment of the present disclosure.

FIG. 23 is a schematic diagram (part 3) of the cross section of the imaging element 100 according to the second modification example of the third embodiment of the present disclosure.

FIG. 24 is a schematic diagram (part 4) of the cross section of the imaging element 100 according to the second modification example of the third embodiment of the present disclosure.

FIG. 25 is a schematic diagram of a cross section of an imaging element 100 according to a fourth embodiment of the present disclosure.

FIG. 26 is a perspective view of the imaging element 100 according to the fourth embodiment of the present disclosure.

FIG. 27 is a cross-sectional view for describing a part of a manufacturing process of a manufacturing method of the imaging element 100 according to the fourth embodiment of the present disclosure.

FIG. 28 is a schematic diagram of a cross section of an imaging element 100 according to a first modification example of the fourth embodiment of the present disclosure.

FIG. 29 is an explanatory diagram (part 1) for describing detailed workability of an imaging element 100 according to a second modification example of the fourth embodiment of the present disclosure.

FIG. 30 is an explanatory diagram (part 2) for describing the detailed workability of the imaging element 100 according to the second modification example of the fourth embodiment of the present disclosure.

FIG. 31 is an explanatory diagram (part 3) for describing the detailed workability of the imaging element 100 according to the second modification example of the fourth embodiment of the present disclosure.

FIG. 32 is an explanatory diagram illustrating a plane of an imaging element 100 according to an embodiment (modification example) of the present disclosure.

FIG. 33 is an explanatory diagram illustrating a part of a cross section of a semiconductor substrate 300 of an imaging element 100 of each structure according to the embodiment (modification example) of the present disclosure.

FIG. 34 is an explanatory diagram illustrating an example of a schematic functional configuration of a camera 700 to which a technology according to the present disclosure can be applied.

FIG. 35 is a block diagram illustrating an example of a schematic functional configuration of a smartphone 900 to which the technology according to the present disclosure can be applied.

### DESCRIPTION OF EMBODIMENTS

In the following, preferred embodiments of the present disclosure will be described in detail with reference to the accompanying drawings. Note that the same reference signs are assigned to components having substantially the same functional configuration, and overlapped description is omitted in the present specification and the drawings. In addition, in the present specification and the drawings, a plurality of components having substantially the same or similar functional configurations may be distinguished by assignment of different alphabets after the same reference sign. However, in a case where it is not specifically necessary to distinguish the plurality of components having substantially the same or similar functional configurations from each other, only the same reference sign is assigned.

In addition, the drawings referred to in the following description are drawings for describing an embodiment of the present disclosure and promoting understanding thereof, and shapes, dimensions, ratios, and the like illustrated in the drawings may be different from actual ones for easy understanding. Furthermore, imaging devices illustrated in the drawings can be appropriately modified in design in consideration of the following description and known technologies.

In addition, the drawings referred to in the following description are drawings for describing an embodiment of the present disclosure and promoting understanding thereof, and shapes, dimensions, ratios, and the like illustrated in the drawings may be different from actual ones for easy understanding. Furthermore, imaging devices illustrated in the drawings can be appropriately modified in design in consideration of the following description and known technologies. Furthermore, in description using a cross-sectional view of an imaging device, unless otherwise specified, an up-down direction of a stacked structure of the imaging device corresponds to a relative direction of a case where a light receiving surface that light incident on the imaging device enters is an upper side, and may be different from an up-down direction according to actual gravitational acceleration.

Furthermore, the shapes and dimensions expressed in the following description not only mean shapes and dimensions defined mathematically or geometrically but also mean inclusion of similar shapes and dimensions having a difference (error/distortion) to an extent allowable in an operation of the imaging device and a manufacturing process of the imaging device. Furthermore, “the same” or “substantially the same” used for specific shapes and dimensions in the following description not only means a case of complete mathematical or geometric matching, and it is assumed that a case of having a difference (error/distortion) to the extent allowable in the operation of the imaging device and the manufacturing process of the imaging device is included.

Furthermore, in the following description, “connecting electrically” means connecting a plurality of elements directly or indirectly via another element.

Furthermore, in the following description, “sharing” means that elements different from each other (such as pixels or the like) use another element (such as an on-chip lens or the like) together.

Note that the description will be made in the following order.
1. Schematic configuration of an imaging device
2. Comparative example
2.1 About the comparative example
2.2 Detailed configuration
2.3 Background
3. First Embodiment
3.1 Detailed configuration
3.2 Manufacturing method
3.3 First modification example
3.4 Second modification example
4. Second Embodiment
4.1 Background
4.2 Detailed configuration
4.3 Modification example
5. Third Embodiment
5.1 Detailed configuration
5.2 First modification example
5.3 Second modification example
6. Fourth Embodiment
6.1 Background
6.2 Detailed configuration
6.3 Manufacturing method
6.4 First modification example
6.5 Second modification example
7. Conclusion
7.1 Conclusion
7.2 Other forms
8. Application example
8.1 Example of application to a camera
8.2 Example of application to a smartphone
9. Supplementary note

### 1. Schematic Configuration of an Imaging Device

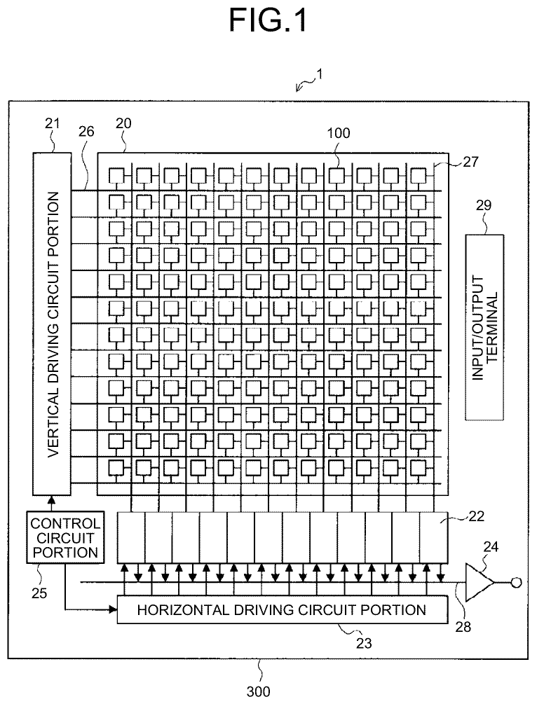

First, a schematic configuration of an imaging device 1 according to an embodiment of the present disclosure will be described with reference to FIG. 1. FIG. 1 is an explanatory diagram illustrating a plane configuration example of the imaging device 1 according to the embodiment of the present disclosure. As illustrated in FIG. 1, the imaging device 1 according to the embodiment of the present disclosure includes a pixel array unit 20 in which a plurality of imaging elements (first imaging element and second imaging element) 100 is arranged in a matrix and peripheral circuit portions provided in such a manner as to surround the pixel array unit 20 on a semiconductor substrate 300 made of, for example, silicon. Furthermore, the imaging device 1 includes, as the peripheral circuit portions, a vertical driving circuit portion 21, a column signal processing circuit portion 22, a horizontal driving circuit portion 23, an output circuit portion 24, a control circuit portion 25, and the like. Hereinafter, details of each block of the imaging device 1 will be described.

### (Pixel Array Unit 20)

The pixel array unit 20 includes the plurality of imaging elements 100 two-dimensionally arranged in a matrix in a row direction and a column direction on the semiconductor substrate 300. Each of the imaging elements 100 is an element that performs photoelectric conversion on incident light, and includes a photoelectric conversion unit (not illustrated) and a plurality of pixel transistors (such as metal-oxide-semiconductor (MOS) transistors) (not illustrated). Specifically, each of the imaging elements 100 can perform photoelectric conversion on light having wavelengths in different wavelength bands (first wavelength band and second wavelength band). Then, the pixel transistors include, for example, four MOS transistors that are a transfer transistor, a selection transistor, a reset transistor, and an amplification transistor. Furthermore, the plurality of imaging elements 100 is two-dimensionally arrayed in the pixel array unit 20, for example, according to a Bayer array. Here, the Bayer array is an array pattern in which the imaging elements 100 that generate charge by absorbing light having a wavelength of green (such as a wavelength of 495 nm to 570 nm) are arranged in a checkered pattern, and the imaging elements 100 that generate charge by absorbing light having a wavelength of red (such as a wavelength of 620 nm to 750 nm) and the imaging elements 100 that generate charge by absorbing light having a wavelength of blue (such as a wavelength of 450 nm to 495 nm) are alternately arranged in every other column in a remaining portion. Note that a detailed structure of the imaging element 100 will be described later.

### (Vertical Driving Circuit Portion 21)

The vertical driving circuit portion 21 includes, for example, a shift register, selects a pixel driving wiring line 26, supplies a pulse for driving the imaging elements 100 to the selected pixel driving wiring line 26, and drives the imaging elements 100 in units of rows. That is, the vertical driving circuit portion 21 selectively scans the imaging elements 100 of the pixel array unit 20 sequentially in a vertical direction (up-down direction in FIG. 1) in units of rows, and supplies a pixel signal based on a signal charge generated according to an amount of light received by a photoelectric conversion unit (not illustrated) of each of the imaging elements 100 to a column signal processing circuit portion 22 (described later) through a vertical signal line 27.

### (Column Signal Processing Circuit Portion 22)

The column signal processing circuit portion 22 is arranged for each column of the imaging elements 100, and performs signal processing such as noise removal for each pixel column on the pixel signals output from the imaging elements 100 in one row. For example, the column signal processing circuit portion 22 performs signal processing such as correlated double sampling (CDS) and analog-digital (AD) conversion in order to remove fixed pattern noise unique to pixels.

### (Horizontal Driving Circuit Portion 23)

The horizontal driving circuit portion 23 includes, for example, a shift register, sequentially selects each of the column signal processing circuit portions 22 described above by sequentially outputting horizontal scanning pulses, and causes each of the column signal processing circuit portions 22 to output a pixel signal to a horizontal signal line 28.

### (Output Circuit Portion 24)

The output circuit portion 24 performs signal processing on the pixel signals sequentially supplied from the column signal processing circuit portions 22 described above through the horizontal signal line 28, and performs an output thereof. The output circuit portion 24 may function as, for example, a functional unit that performs buffering, or may perform processing such as a black level adjustment, a column variation correction, and various kinds of digital signal processing. Note that buffering means temporarily storing the pixel signals in order to compensate for differences in processing speed and transfer speed when the pixel signals are exchanged. Furthermore, an input/output terminal 29 is a terminal for exchanging signals with an external device.

### (Control Circuit Portion 25)

The control circuit portion 25 receives an input clock and data instructing an operation mode or the like, and outputs data such as internal information of the imaging device 1. That is, the control circuit portion 25 generates a clock signal and a control signal serving as reference of operation of the vertical driving circuit portion 21, the column signal processing circuit portion 22, the horizontal driving circuit portion 23, and the like on the basis of a vertical synchronization signal, a horizontal synchronization signal, and a master clock. Then, the control circuit portion 25 outputs the generated clock signal and control signal to the vertical driving circuit portion 21, the column signal processing circuit portion 22, the horizontal driving circuit portion 23, and the like.

Note that the imaging device 1 according to the present embodiment is not limited to the configuration illustrated in FIG. 1.

### 2. Comparative Example

<2.1 about the Comparative Example>

Next, before description of details of embodiments of the present disclosure, a comparative example studied by the present inventors before creation of the embodiments of the present disclosure will be described. First, a background of creation of the comparative example will be described. Note that here, the comparative example means an imaging element 100a that has been repeatedly studied by the present inventors before the embodiments of the present disclosure are made.

The comparative example compared with the embodiments of the present disclosure has been created during the study of providing phase difference detection pixels on the entire surface of the pixel array unit 20 of the imaging device 1 (all-pixel phase difference detection) in order to further improve an autofocus function, that is, to improve accuracy of phase difference detection while avoiding deterioration of a captured image. In the comparative example, an imaging element 100a capable of functioning as one imaging element at the time of imaging and functioning as a pair of phase difference detection pixels at the time of phase difference detection is provided on an entire surface of a pixel array unit 20 (dual photodiode structure). In the comparative example that enables all-pixel phase difference detection, since the phase difference detection pixels are provided on the entire surface, accuracy of the phase difference detection can be improved.

Furthermore, in the comparative example, an element that optically and electrically isolates the phase difference detection pixels and is to prevent outputs of the pair of phase difference detection pixels from being mixed at the time of the phase difference detection is provided. In addition, in the comparative example, an overflow path is provided between the pair of phase difference detection pixels in order to prevent deterioration of a captured image. Specifically, at the time of normal imaging, when charge of either one pixel of the phase difference detection pixels is about to be saturated, the charge is transferred to the other pixel via the overflow path, whereby the saturation of the one pixel can be prevented. Then, by providing such an overflow path, it is possible to secure linearity of pixel signals output from the imaging element 100a, and to prevent deterioration of the captured image.

Hereinafter, a detailed configuration of the imaging element 100a of such a comparative example will be sequentially described.

### <2.2 Detailed Configuration>

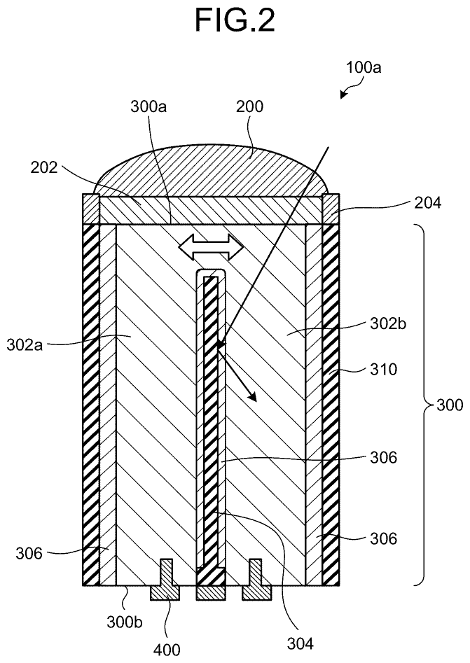

A detailed configuration of the imaging element 100a according to the comparative example will be described with reference to FIG. 2. FIG. 2 is a schematic diagram of a cross section of the imaging element 100a according to the comparative example, and specifically corresponds to a cross section obtained by cutting of the imaging element 100a in a thickness direction of a semiconductor substrate 300.

As illustrated in FIG. 2, the imaging element 100a according to the comparative example includes an on-chip lens 200, a color filter 202, a light shielding portion 204, a semiconductor substrate 300, and a transfer gate 400. Furthermore, in the present comparative example, the semiconductor substrate 300 includes a pair of pixels 302a and 302b each of which includes a photoelectric conversion unit (not illustrated). Furthermore, the semiconductor substrate 300 includes a pixel isolation portion 304 that isolates the pair of pixels 302a and 302b, and includes an element isolation wall 310 surrounding the pixels 302a and 302b, and a diffusion region 306 provided around the pixel isolation portion 304 and the element isolation wall 310.

Hereinafter, a stacked structure of the imaging element 100a according to the comparative example will be described. In the following description, the description will be made in order from an upper side (side of a light receiving surface 300a) to a lower side (surface 300b) in FIG. 2.

As illustrated in FIG. 2, the imaging element 100a includes one on-chip lens 200 that is provided above the light receiving surface 300a of the semiconductor substrate 300 and that collects incident light on the photoelectric conversion units (not illustrated). The imaging element 100a has a structure in which the pair of pixels 302a and 302b is provided for the one on-chip lens 200. That is, the on-chip lens 200 is shared by the two pixels 302a and 302b.

Then, the incident light collected by the on-chip lens 200 is emitted to each of the photoelectric conversion units (not illustrated) of the pair of pixels 302a and 302b through the color filter 202 provided below the on-chip lens 200. The color filter 202 is any of a color filter that transmits a red wavelength component, a color filter that transmits a green wavelength component, or a color filter that transmits a blue wavelength component. Note that the color filter 202 may not be provided in the present comparative example.

Furthermore, the light shielding portion 204 is provided on the light receiving surface 300a of the semiconductor substrate 300 in such a manner as to surround the color filter 202. Since the light shielding portion 204 is provided between adjacent imaging elements 100a, it is possible to perform light shielding between the imaging elements 100a in order to control crosstalk between the adjacent imaging elements 100a and further improve accuracy in phase difference detection.

Furthermore, for example, in a predetermined unit region in the semiconductor substrate 300 of a second conductive type (such as a p-type), a photoelectric conversion unit (not illustrated) having an impurity of a first conductive type (such as an n-type) is provided for each of the adjacent pixels 302a and 302b. The photoelectric conversion unit can generate charge by absorbing light that has a red wavelength component, a green wavelength component, or a blue wavelength component and that is incident through the color filter 202. Then, in the present comparative example, the photoelectric conversion unit of the pixel 302a and the photoelectric conversion unit of the pixel 302b can function as a pair of phase difference detection pixels at the time of the phase difference detection. That is, in the present comparative example, it is possible to detect a phase difference by detecting a difference between pixel signals based on the charge generated by the photoelectric conversion unit of the pixel 302a and the photoelectric conversion unit of the pixel 302b. In addition, in the present comparative example, the pair of phase difference detection pixels 302a and 302b can function as the one imaging element 100a.

Specifically, in each of the photoelectric conversion units (not illustrated), an amount of charge to be generated, that is, sensitivity changes depending on an incident angle of light with respect to own optical axis (axis vertical to the light receiving surface 300a). For example, the photoelectric conversion unit has the highest sensitivity in a case where the incident angle is 0 degrees, and the sensitivity of the photoelectric conversion unit has a line-symmetric relationship with the incident angle with the incident angle being 0 degrees as an object axis. Thus, in the photoelectric conversion unit of the pixel 302a and the photoelectric conversion unit of the pixel 302b, light from the same point enters at different incident angles, and charges of amounts corresponding to the incident angles are generated, whereby a deviation (phase difference) is generated in the detected image. That is, it is possible to detect the phase difference by detecting the difference between the pixel signals based on the amounts of charge generated by the photoelectric conversion unit of the pixel 302a and the photoelectric conversion unit of the pixel 302b. Thus, for example, such a difference (phase difference) between the pixel signals is detected as a difference signal in a detection unit (not illustrated) of the output circuit portion 24, a defocus amount is calculated and an image forming lens (not illustrated) is adjusted (moved) on the basis of the detected phase difference, whereby autofocus can be realized. Note that although it has been described that the phase difference is detected as the difference between the pixel signals of the photoelectric conversion unit of the pixel 302a and the photoelectric conversion unit of the pixel 302b in the above description, the present comparative example is not limited thereto. In the present comparative example, for example, the phase difference may be detected as a ratio of the pixel signals of the photoelectric conversion unit of the pixel 302a and the photoelectric conversion unit of the pixel 302b.

Furthermore, in the comparative example, the two pixels 302a and 302b are physically (optically) and electrically isolated by the pixel isolation portion 304. The pixel isolation portion 304 includes, as deep trench isolation (DTI), a groove portion (trench) (not illustrated) provided in such a manner as to extend in the semiconductor substrate 300 in the thickness direction of the semiconductor substrate 300 from a side of the surface 300b facing a light receiving surface 300a, and a material that includes an oxide film or a metal film such as a silicon oxide film (SiO₂), a silicon nitride film, amorphous silicon, polycrystalline silicon, aluminum, or tungsten and that is embedded in the trench. In the present comparative example, since the pixel isolation portion 304 penetrates a part of the semiconductor substrate 300, the pair of pixels 302a and 302b can be effectively isolated. As a result, generation of color mixture can be controlled, and the accuracy of the phase difference detection can be further improved. Note that in the present modification example, the pixel isolation portion 304 only needs to be provided in such a manner as to penetrate at least a part of the semiconductor substrate 300 in the thickness direction of the semiconductor substrate 300, and is not specifically limited.

Furthermore, in the present comparative example, a diffusion region 306 including an impurity of the second conductive type (such as the p-type) may be formed around the pixel isolation portion 304. By providing the diffusion region 306, it is possible to electrically isolate the pair of pixels 302a and 302b and to prevent color mixture. Thus, the accuracy of the phase difference detection can be further improved.

Furthermore, in the comparative example, as illustrated in FIG. 2, a diffusion region (not illustrated) is formed above the pixel isolation portion 304 (light receiving surface 300a) by introduction of an impurity of the first conductive type (such as the n-type) by ion implantation, for example. The diffusion region can function as an overflow path (may be referred to as a “path” in the present specification) (indicated by an arrow in FIG. 2) capable of exchanging the generated charge between the pixels 302a and 302b. Specifically, at the time of normal imaging, when the charge of either one pixel of the pixels 302a and 302b is about to be saturated, the charge is transferred to the other pixel via the overflow path, whereby the saturation of the one pixel can be prevented. Then, by providing such an overflow path, it is possible to secure linearity of the pixel signals output from the imaging element 100a, and to prevent deterioration of the captured image. Note that in the present modification example, the overflow path is not necessarily provided above the pixel isolation portion 304, and may be provided below the pixel isolation portion 304, for example.

Furthermore, in the comparative example, the element isolation wall 310 that surrounds the pixels 302a and 302b in the unit region, penetrates the semiconductor substrate 300 in the thickness direction of the semiconductor substrate 300, and physically isolates the adjacent imaging elements 100a is provided in the semiconductor substrate 300. The element isolation wall 310 includes the groove portion (trench) (not illustrated) provided in such a manner as to penetrate the semiconductor substrate 300 in the thickness direction of the semiconductor substrate 300, and the material including the oxide film or the metal film embedded in the trench.

Furthermore, in the comparative example, a diffusion region 306 including an impurity of the second conductive type (such as the p-type) may be formed around the element isolation wall 310.

Furthermore, in the comparative example, the charge generated in the photoelectric conversion unit (not illustrated) of the pixel 302a and the photoelectric conversion unit (not illustrated) of the pixel 302b are transferred through the transfer gate 400 of the transfer transistor (one type of the pixel transistor) provided on the surface 300b located on the opposite side of the light receiving surface 300a of the semiconductor substrate 300. The transfer gate 400 can be formed of, for example, a metal film. Then, the charge may be accumulated in, for example, a floating diffusion portion (charge accumulation portion) (not illustrated) provided in a semiconductor region that has the first conductive type (such as the n-type) and that is provided in the semiconductor substrate 300. Note that in the comparative example, the floating diffusion portion is not necessarily provided in the semiconductor substrate 300, and may be provided, for example, in another substrate (not illustrated) stacked on the semiconductor substrate 300.

Furthermore, on the surface 300b of the semiconductor substrate 300, a plurality of various pixel transistors (not illustrated) that are other than the above-described transfer transistor and that read out the charge as a pixel signal may be provided. Furthermore, in the comparative example, the pixel transistors may be provided on the semiconductor substrate 300, or may be provided on another substrate (not illustrated) stacked on the semiconductor substrate 300.

As described above, according to the comparative example, at the time of the phase difference detection, since the pixel isolation portion 304 that performs physical isolation of the pair of pixels 302a and 302b and the diffusion region 306 that performs electrical isolation thereof are provided, and the overflow path (not illustrated) is provided between the pair of pixels 302a and 302b, it is possible to prevent deterioration of the captured image while improving the accuracy of the phase difference detection. Specifically, in the comparative example, the pair of pixels 302a and 302b can be effectively isolated by the pixel isolation portion 304 and the diffusion region 306. As a result, generation of the color mixture can be controlled, and the accuracy of the phase difference detection can be further improved. Furthermore, in the comparative example, since the overflow path is provided, when the charge of either one of the pixels 302a and 302b is about to be saturated at the time of the normal imaging, saturation of one pixel can be prevented by transfer of the charge to the other pixel via the overflow path. Thus, according to the comparative example, by providing such an overflow path, it is possible to secure the linearity of the pixel signals output from the imaging element 100a, and to prevent deterioration of the captured image.

### <2.3 Background>

Next, a background of creation of embodiments of the present disclosure created by the present inventors will be described with reference to FIG. 2.

In the comparative example illustrated in FIG. 2, as described above, the two pixels (photoelectric conversion units (not illustrated)) 302a and 302b are physically (optically) and electrically isolated by the pixel isolation portion 304. However, as indicated by an arrow in FIG. 2 (thin arrow in the drawing), light obliquely incident on the light receiving surface 300a of the imaging element 100a is reflected by a side surface of the pixel isolation portion 304 of the imaging element 100a, and reaches a photoelectric conversion unit (not illustrated) of a pixel 302 or a photoelectric conversion unit (not illustrated) of a pixel 302 of an imaging element 100a adjacent to the imaging element 100a. In such a case, since accuracy (isolation ratio) of the phase difference detection of the pixels 302a and 302b in the same imaging element 100a is deteriorated, the phase difference detection is easily affected by noise, and high-speed autofocus operation may be difficult. Furthermore, in such a case, color mixture is generated between adjacent imaging elements 100a that detect light of different colors.

Thus, in view of such a situation, the present inventors have created embodiments of the present disclosure described below. In the embodiments of the present disclosure created by the present inventors, a surface of a pixel isolation portion 304 is made to be an uneven surface, whereby reflection on the surface of the pixel isolation portion 304 is reduced. As a result, in the present embodiments, it is possible to control deterioration in accuracy of phase difference detection of pixels 302a and 302b in the same imaging element 100 and generation of color mixture between adjacent imaging elements 100 that detect light of different colors. Hereinafter, details of such embodiments of the present disclosure will be sequentially described.

### 3. First Embodiment

### <3.1 Detailed Configuration>

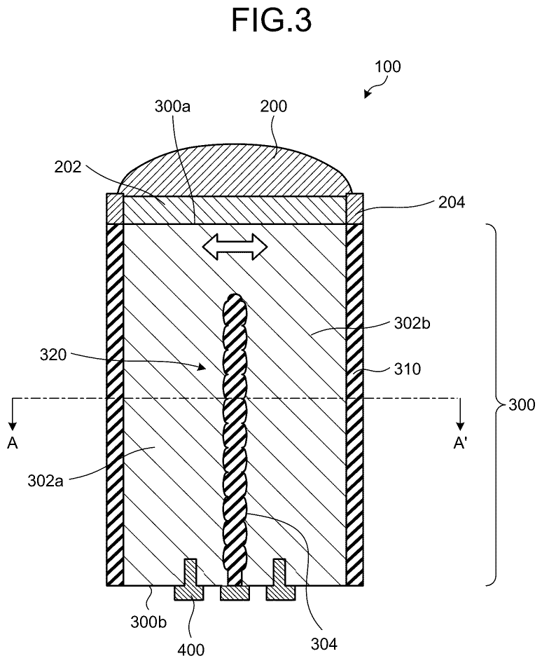

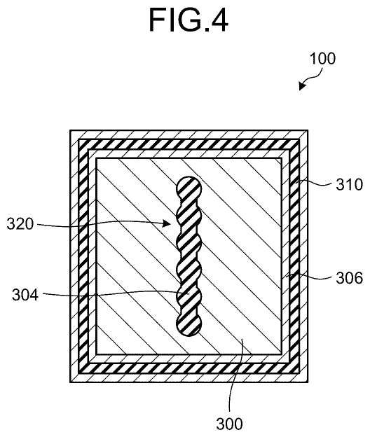

First, a detailed configuration of an imaging element 100 according to the first embodiment of the present disclosure will be described with reference to FIG. 3 and FIG. 4. FIG. 3 is a schematic diagram of a cross section of the imaging element 100 according to the first embodiment of the present disclosure, and is specifically a schematic diagram of a cross section of the imaging element 100 cut in a thickness direction of a semiconductor substrate 300. FIG. 4 is also a schematic diagram of a cross section of the imaging element 100 according to the first embodiment of the present disclosure, and is specifically a schematic diagram of a cross section of a case where the imaging element 100 is cut along a line A-A′ illustrated in FIG. 3. Note that in FIG. 3 and FIG. 4, illustration of a diffusion region 306 or a part thereof is omitted for easy understanding. In addition, in the following description, an element common with the comparative example is denoted by a common reference sign in the drawings, and description thereof will be omitted.

As illustrated in FIG. 3, the imaging element 100 according to the present embodiment includes an on-chip lens 200, a color filter 202, a light shielding portion 204, a semiconductor substrate 300, and a transfer gate 400, similarly to the comparative example. Furthermore, also in the present embodiment, the semiconductor substrate 300 includes a pair of pixels 302a and 302b each of which includes a photoelectric conversion unit (not illustrated). In addition, the semiconductor substrate 300 includes a pixel isolation portion 304 that isolates the pair of pixels 302a and 302b from each other and an element isolation wall 310 that surrounds the pixels 302a and 302b. Furthermore, although not illustrated in the present embodiment, the imaging element 100 may include a diffusion region 306 provided around the pixel isolation portion 304 and the element isolation wall 310.

Hereinafter, a stacked structure of the imaging element 100 according to the present embodiment will be described. In the following description, the description will be made in order from an upper side (side of a light receiving surface 300a) to a lower side (surface 300b) in FIG. 3.

As illustrated in FIG. 3, similarly to the comparative example, the imaging element 100 according to the present embodiment includes one on-chip lens 200 that is provided above the light receiving surface 300a of the semiconductor substrate 300 and that collects incident light on the photoelectric conversion units (not illustrated). The imaging element 100 has a structure in which the pair of pixels 302a and 302b is provided for the one on-chip lens 200. That is, the on-chip lens 200 is shared by the two pixels 302a and 302b. Note that the on-chip lens 200 can be formed of, for example, a silicon nitride film (SiN), or a resin-based material such as a styrene resin, an acrylic resin, a styrene-acrylic copolymer resin, or a siloxane resin.

Then, the incident light collected by the on-chip lens 200 is emitted to each of the photoelectric conversion units (not illustrated) of the pair of pixels 302a and 302b through the color filter 202 provided below the on-chip lens 200. The color filter 202 is any of a color filter that transmits a red wavelength component, a color filter that transmits a green wavelength component, or a color filter that transmits a blue wavelength component. For example, the color filter 202 can be formed of, a material in which pigment or dye is dispersed in a transparent binder such as silicone. Note that the color filter 202 may not be provided in the present embodiment.

Furthermore, the light shielding portion 204 is provided on the light receiving surface 300a of the semiconductor substrate 300 in such a manner as to surround the color filter 202. Since the light shielding portion 204 is provided between adjacent imaging elements 100a, it is possible to perform light shielding between the imaging elements 100a in order to control crosstalk between the adjacent imaging elements 100 and further improve accuracy in phase difference detection. The light shielding portion 204 can be formed of, for example, a metal material or the like including tungsten (W), aluminum (Al), copper (Cu), titanium (Ti), molybdenum (Mo), nickel (Ni), or the like.

Furthermore, for example, in a predetermined unit region in the semiconductor substrate 300 of a second conductive type (such as a p-type), a photoelectric conversion unit (not illustrated) having an impurity of a first conductive type (such as an n-type) is provided for each of the adjacent pixels 302a and 302b. As described above, the photoelectric conversion unit generates charge by absorbing light that has a red wavelength component, a green wavelength component, or a blue wavelength component and that is incident through the color filter 202. Then, similarly to the comparative example, the photoelectric conversion unit of the pixel 302a and the photoelectric conversion unit of the pixel 302b can function as a pair of phase difference detection pixels at the time of phase difference detection also in the present embodiment. That is, in the present embodiment, it is possible to detect a phase difference by detecting a difference between pixel signals based on the charge generated by the photoelectric conversion unit of the pixel 302a and the photoelectric conversion unit of the pixel 302b. In addition, similarly to the comparative example, the pair of phase difference detection pixels 302a and 302b can function as the one imaging element 100 in the present embodiment.

Furthermore, in the present embodiment, as illustrated in FIG. 3 and FIG. 4, the two pixels (photoelectric conversion units (not illustrated)) 302a and 302b are physically (optically) and electrically isolated by the pixel isolation portion 304. As illustrated in FIG. 3, the pixel isolation portion 304 includes, as deep trench isolation (DTI), a groove portion (trench) (not illustrated) provided in such a manner as to penetrate a part of the semiconductor substrate 300 in the thickness direction of the semiconductor substrate 300 from a side of the surface 300b facing the light receiving surface 300a, and a high refractive index material embedded in the trench. For example, the high refractive index material is made of a material having a refractive index (such as 2.1 to 2.5) close to a refractive index of silicon (3.8) of the semiconductor substrate 300, and examples thereof include a titanium oxide film (TiO₂) and a tantalum oxide film (TaO). In the present embodiment, since the pixel isolation portion 304 is formed of such a high refractive index material, a difference in the refractive index from the semiconductor substrate 300 can be reduced, and reflection on the surface of the pixel isolation portion 304 can be controlled. Furthermore, in the present embodiment, as illustrated in FIG. 4, the pixel isolation portion 304 is provided in the vicinity of a center of the imaging element 100 in such a manner as to extend in an up-down direction in the drawing.

Furthermore, in the present embodiment, as illustrated in FIG. 3 and FIG. 4, the side surface of the pixel isolation portion 304 includes an uneven surface having unevenness 320. In the present embodiment, since the side surface of the pixel isolation portion 304 includes the surface having the unevenness 320, light is scattered by the unevenness 320. Thus, specular reflection intensity on the side surface of the pixel isolation portion 304 is reduced, and reflection can be controlled. Specifically, as illustrated in FIG. 3 and FIG. 4, the unevenness 320 of the pixel isolation portion 304 has a hemispherical protrusion. Note that in the present embodiment, the unevenness 320 is not limited to the hemispherical shape, and may have a conical or pyramidal protrusion. However, in the present embodiment, the unevenness 320 preferably has the hemispherical protrusion from a viewpoint of reducing the reflection.

Furthermore, according to the study by the present inventors, the unevenness 320 of the pixel isolation portion 304 in the present embodiment may be periodic, or may not be circumferential. In a case where the unevenness 320 is periodic, according to optical simulation by the present inventors, it is known that an effect of reducing the reflection can be obtained when the unevenness 320 is repeated in a period of, for example, about 200 nm.

That is, in the present embodiment, since the side surface of the pixel isolation portion 304 includes the surface having the unevenness 320, the reflection on the side surface of the pixel isolation portion 304 can be controlled.

Furthermore, also in the present embodiment, although not illustrated, a diffusion region 306 including an impurity of the second conductive type (such as the p-type) may be formed around the pixel isolation portion 304. By providing the diffusion region 306, it is possible to electrically isolate the pair of pixels 302a and 302b and to prevent color mixture. Thus, the accuracy of the phase difference detection can be further improved.

Furthermore, in the present embodiment, as illustrated in FIG. 3, a diffusion region (not illustrated) is formed above the pixel isolation portion 304 (side of the light receiving surface 300a) by introduction of an impurity of the first conductive type (such as the n-type), for example, by ion implantation. The diffusion region can function as an overflow path (indicated by an arrow in FIG. 3) capable of exchanging the generated charge between the pixels 302a and 302b. Specifically, at the time of normal imaging, when the charge of either one pixel of the pixels 302a and 302b is about to be saturated, the charge is transferred to the other pixel via the overflow path, whereby the saturation of the one pixel can be prevented. Then, by providing such an overflow path, it is possible to secure linearity of the pixel signals output from the imaging element 100, and to prevent deterioration of the captured image.

Furthermore, in the present embodiment, as illustrated in FIG. 3 and FIG. 4, in the semiconductor substrate 300, the element isolation wall 310 that surrounds the pixels 302a and 302b in the unit region and penetrates the semiconductor substrate 300 in the thickness direction of the semiconductor substrate 300 is provided. The element isolation wall 310 can physically isolates the adjacent imaging elements 100 that detect light of colors different from each other. Specifically, the element isolation wall 310 is made of a groove portion (trench) (not illustrated) provided in such a manner as to penetrate the semiconductor substrate 300 in the thickness direction of the semiconductor substrate 300, and a material that includes an oxide film or a metal film such as a silicon oxide film, a silicon nitride film, amorphous silicon, polycrystalline silicon, a titanium oxide film, aluminum, or tungsten and that is embedded in the trench. Note that in the present embodiment, a side surface of the element isolation wall 310 may include an uneven surface having the unevenness 320, similarly to the side surface of the pixel isolation portion 304. In such a manner, since reflection on the side surface of the element isolation wall 310 can be controlled, it is possible to control deterioration in accuracy of the phase difference detection of the pixels 302a and 302b in the same imaging element 100, and generation of color mixture between the adjacent imaging elements 100.

Furthermore, as illustrated in FIG. 4, in the present embodiment, a diffusion region 306 including the impurity of the second conductive type (such as the p-type) may be formed around the element isolation wall 310. For example, the diffusion region 306 can be formed by conformal doping of the impurity of the second conductive type (such as the p-type) via the element isolation wall 310.

Furthermore, similarly to the comparative example, also in the present embodiment, the charge generated in the photoelectric conversion unit (not illustrated) of the pixel 302a and the photoelectric conversion unit (not illustrated) of the pixel 302b are transferred through the transfer gate 400 of a transfer transistor (one type of a pixel transistor) provided on the surface 300b located on the opposite side of the light receiving surface 300a of the semiconductor substrate 300. The transfer gate 400 can be formed of, for example, a metal film. Then, the charge may be accumulated in, for example, a floating diffusion portion (charge accumulation portion) (not illustrated) provided in a semiconductor region that has the first conductive type (such as the n-type) and that is provided in the semiconductor substrate 300. Note that in the present example, the floating diffusion portion is not necessarily provided in the semiconductor substrate 300, and may be provided, for example, in another substrate (not illustrated) stacked on the semiconductor substrate 300.

Furthermore, on the surface 300b of the semiconductor substrate 300, a plurality of various pixel transistors (not illustrated) that are other than the above-described transfer transistor and that read out the charge as a pixel signal may be provided. Furthermore, also in the present embodiment, the pixel transistors may be provided on the semiconductor substrate 300, or may be provided on another substrate (not illustrated) stacked on the semiconductor substrate 300.

As described above, in the present embodiment, since the side surface of the pixel isolation portion 304 includes the surface having the unevenness 320, the reflection on the side surface of the pixel isolation portion 304 can be controlled. As a result, in the present embodiment, it is possible to control deterioration in accuracy of the phase difference detection of the pixels 302a and 302b in the same imaging element 100 and generation of the color mixture between the adjacent imaging elements 100. Note that the imaging element 100 according to the present embodiment is not limited to the configuration illustrated in FIG. 3 and FIG. 4.

### <3.2 Manufacturing Method>

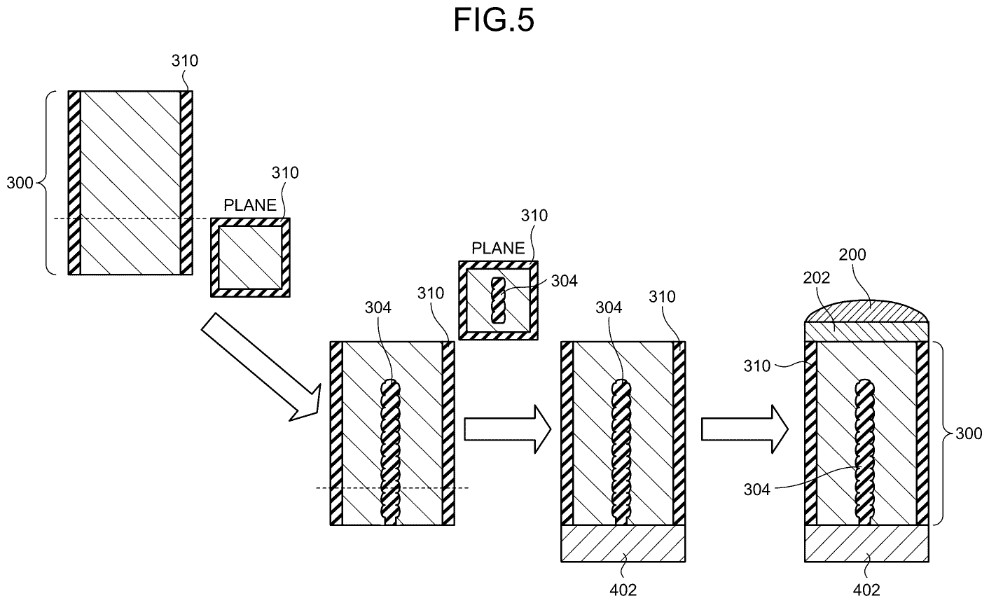

Next, a part of a manufacturing process (manufacturing method) of the imaging element 100 according to the present embodiment will be described with reference to FIG. 5. FIG. 5 is a cross-sectional view for describing a part of the manufacturing process of the manufacturing method of the imaging element 100 according to the present embodiment, and specifically corresponds to a cross-sectional view corresponding to the cross-sectional view illustrated in FIG. 3, and the cross-sectional view illustrated in FIG. 4.

First, as illustrated on a left side of FIG. 5, a trench penetrating the semiconductor substrate 300 is formed in the semiconductor substrate 300, and an insulating material is embedded in the trench, whereby the element isolation wall 310 is formed. A region of the semiconductor substrate 300 which region is surrounded by the element isolation wall 310 is a unit region in which the one imaging element 100 is provided.

Then, a trench penetrating a part of the semiconductor substrate 300 from the surface 300b of the semiconductor substrate 300 in the thickness direction of the semiconductor substrate 300 is formed. At this time, the trench is formed in such a manner that a side surface of the trench is uneven. For example, a mask having a pattern of the trench is formed on the surface 300b of the semiconductor substrate 300. Furthermore, it is possible to form the trench having the uneven shape by etching the semiconductor substrate 300 along an opening of the mask while controlling a bias and a deposition/etching rate in a Bosch method that is one type of reactive ion etching (RIE). In the Bosch method, etching to the semiconductor substrate 300 and protection of the etched sidewall (deposition on the surface) are repeatedly performed, whereby the trench having the uneven shape can be formed. Then, by embedding a high refractive material in the trench formed in such a manner, it is possible to form the pixel isolation portion 304 in a manner illustrated second from a left side of FIG. 5.

Furthermore, as illustrated third from the left side of FIG. 5, a wiring layer 402 including a pixel transistor, a wiring line, and the like is formed on the surface 300b of the semiconductor substrate 300. Then, as illustrated on a right side of FIG. 5, the color filter 202 and the on-chip lens 200 are formed on the light receiving surface 300a of the semiconductor substrate 300.

The imaging element 100 according to the present embodiment can be formed in the above manner.

### 3.3 First Modification Example

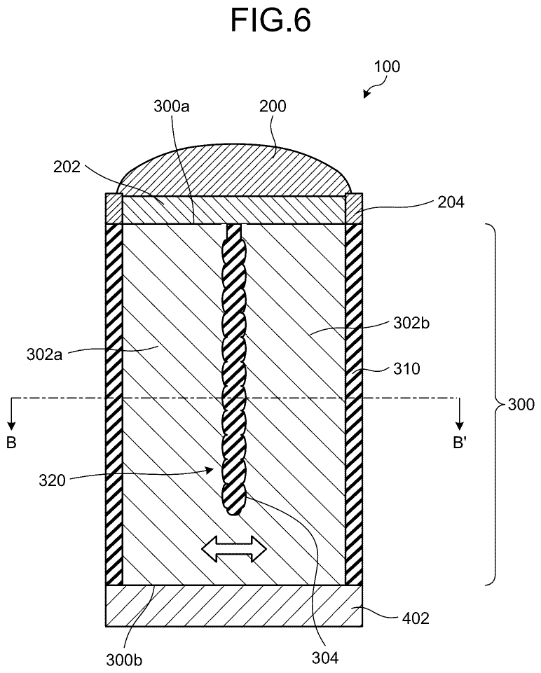

In the above-described embodiment, the pixel isolation portion 304 is not limited to what penetrates a part of the semiconductor substrate 300 in the thickness direction of the semiconductor substrate 300 from the side of the surface 300b. For example, a pixel isolation portion 304 may penetrate a part of a semiconductor substrate 300 in a thickness direction of the semiconductor substrate 300 from a side of a light receiving surface 300a. Thus, a configuration of such an imaging element 100 according to the first modification example of the present embodiment will be described with reference to FIG. 6. FIG. 6 is a schematic diagram of a cross section of the imaging element 100 according to the first modification example of the present embodiment, and corresponds to FIG. 3. Note that in the following description, an element common with the above-described present embodiment is denoted by a common reference sign in the drawing, and description thereof will be omitted.

In the present modification example, as illustrated in FIG. 6, a pixel isolation portion 304 that isolates two pixels (photoelectric conversion units (not illustrated)) 302a and 302b includes a groove portion (trench) (not illustrated) provided in such a manner as to penetrate a part of a semiconductor substrate 300 in a thickness direction of the semiconductor substrate 300 from a side of a light receiving surface 300a, and a high refractive index material embedded in the trench. Also in the present modification example, since the pixel isolation portion 304 is formed of the high refractive index material, reflection on a surface of the pixel isolation portion 304 can be controlled.

Furthermore, also in the present modification example, as illustrated in FIG. 6, the side surface of the pixel isolation portion 304 includes an uneven surface having unevenness 320. Specifically, as illustrated in FIG. 6, the unevenness 320 of the pixel isolation portion 304 has a hemispherical protrusion. Note that also in the present modification example, the unevenness 320 is not limited to the hemispherical shape, and may have a conical or pyramidal protrusion.

Furthermore, in the present modification example, as illustrated in FIG. 6, a diffusion region (not illustrated) is formed below the pixel isolation portion 304 (side of a surface 300b) by introduction of an impurity of a first conductive type (such as an n-type), for example, by ion implantation. The diffusion region can function as an overflow path (indicated by an arrow in FIG. 6) capable of exchanging generated charge between the pixels 302a and 302b. Then, also in the present modification example, by providing the overflow path, it is possible to secure linearity of pixel signals output from the imaging element 100, and to prevent deterioration of a captured image.

Note that since a cross section of a case where the imaging element 100 is cut along a line B-B′ in FIG. 6 is similar to that in FIG. 4 described above, description thereof is omitted here.

As described above, in the present modification example, since the side surface of the pixel isolation portion 304 includes the surface having the unevenness 320, reflection on the side surface of the pixel isolation portion 304 can be controlled. As a result, in the present modification example, it is possible to control deterioration in accuracy of phase difference detection of the pixels 302a and 302b in the same imaging element 100 and generation of color mixture between adjacent imaging elements 100.

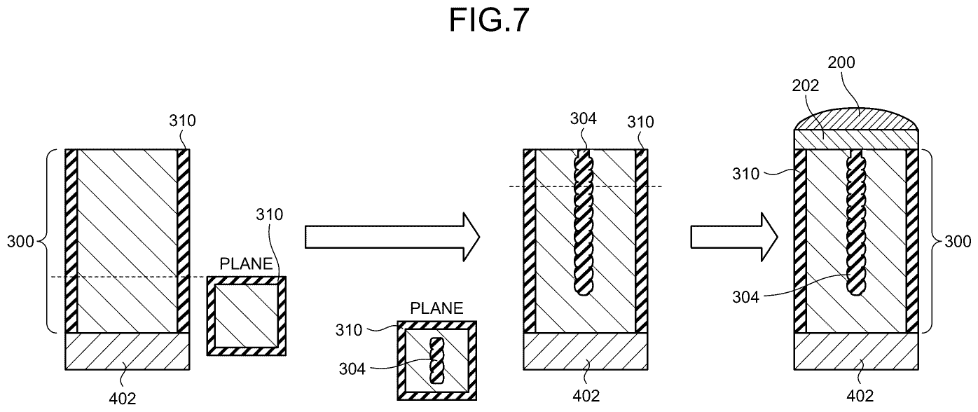

Next, a part of a manufacturing process (manufacturing method) of the imaging element 100 according to the present modification example will be described with reference to FIG. 7. FIG. 7 is a cross-sectional view for describing a part of the manufacturing process of the manufacturing method of the imaging element 100 according to the present modification example, and specifically corresponds to a cross-sectional view corresponding to the cross-sectional view illustrated in FIG. 6, and the cross-sectional view illustrated in FIG. 4.

First, a wiring layer 402 including a pixel transistor, a wiring line, and the like is formed on the surface 300b of the semiconductor substrate 300. Furthermore, a trench penetrating the semiconductor substrate 300 is formed in the semiconductor substrate 300, and an insulating material is embedded in the trench, whereby an element isolation wall 310 is formed. Thus, a form in a manner illustrated on a left side of FIG. 7 can be obtained.

Next, a trench penetrating a part of the semiconductor substrate 300 from the light receiving surface 300a of the semiconductor substrate 300 in the thickness direction of the semiconductor substrate 300 is formed. At this time, by utilization of the Bosch method described above, the trench is formed in such a manner that a side surface of the trench is uneven. Then, by embedding a high refractive material in the trench formed in such a manner, it is possible to form the pixel isolation portion 304 in a manner illustrated second from the left side of FIG. 7.

Furthermore, as illustrated on a right side of FIG. 7, a color filter 202 and an on-chip lens 200 are formed on the light receiving surface 300a of the semiconductor substrate 300. The imaging element 100 according to the present modification example can be formed in the above manner.

### 3.4 Second Modification Example

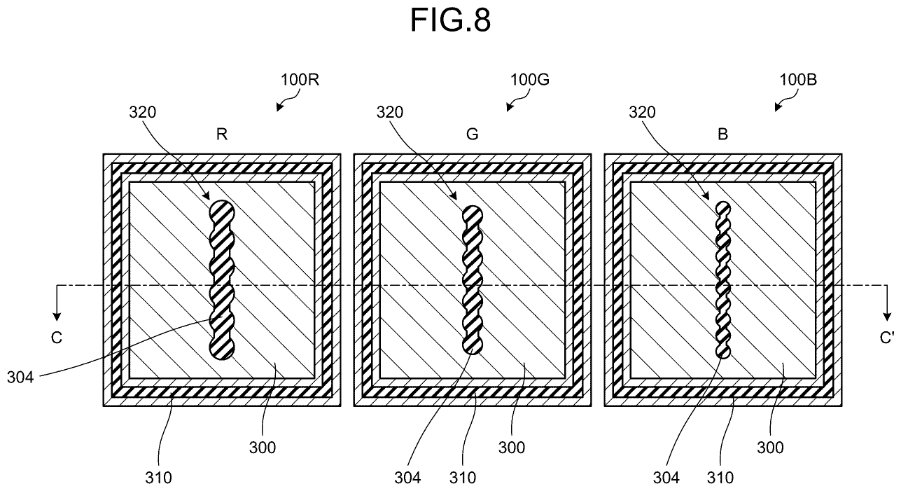

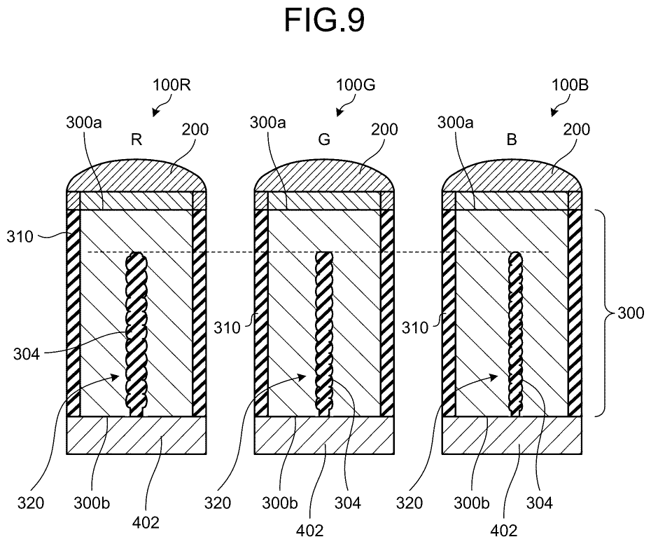

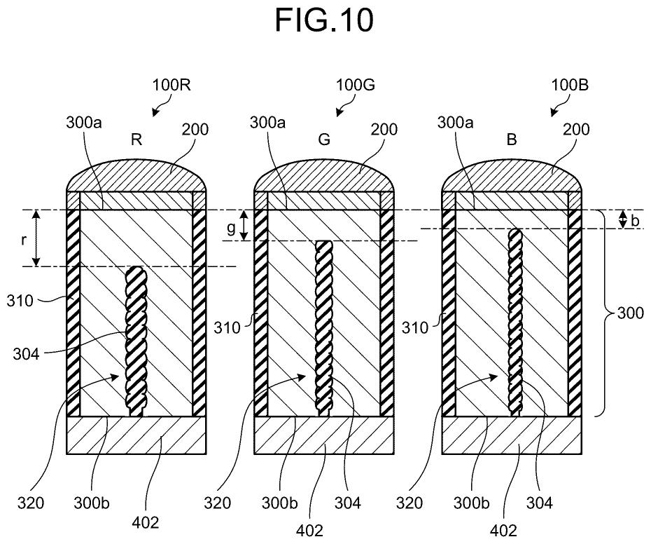

Furthermore, in the present embodiment, a period of the unevenness 320 of the pixel isolation portion 304 is not necessarily substantially the same in all the imaging elements 100, and may be changed according to a wavelength of light detected by an imaging element 100, or a length of a pixel isolation portion 304 along a thickness of a semiconductor substrate 300 may be changed according to the wavelength of the light detected by the imaging element 100. Thus, a configuration of such an imaging element 100 according to the second modification example of the present embodiment will be described with reference to FIG. 8 to FIG. 10. FIG. 8 is a schematic diagram of a cross section of the imaging element 100 according to the second modification example of the first embodiment of the present disclosure, and is specifically a schematic diagram of a cross section of the imaging element 100 cut along a plane of the semiconductor substrate 300. FIG. 9 and FIG. 10 are schematic diagrams of a cross section of the imaging element 100 according to the second modification example of the first embodiment of the present disclosure, and specifically are schematic diagrams of a cross section of the imaging element 100 cut in a thickness direction of a semiconductor substrate 300, that is, a cross section of the semiconductor substrate 300 cut along a line C-C′ illustrated in FIG. 8. Note that in FIG. 8 to FIG. 10, illustration of a diffusion region 306 or a part thereof is omitted for easy understanding. In addition, in the following description, an element common with the above-described present embodiment is denoted by a common reference sign in the drawings, and description thereof will be omitted.

In the present modification example, as illustrated in FIG. 8, similarly to the present embodiment, a side surface of the pixel isolation portion 304 includes an uneven surface having unevenness 320.

In the present modification example, as illustrated in FIG. 8, a period of unevenness 320 on a side surface of a pixel isolation portion 304 of an imaging element 100R that detects red light (for example, a wavelength being 620 nm to 750 nm) is longer than a period of unevenness 320 on a side surface of a pixel isolation portion 304 of an imaging element 100G that detects green light (for example, a wavelength being 495 nm to 570 nm). Furthermore, the period of the unevenness 320 on the side surface of the pixel isolation portion 304 of the imaging element 100G that detects the green light is longer than a period of unevenness 320 on a side surface of a pixel isolation portion 304 of an imaging element 100B that detects blue light (for example, a wavelength being 450 nm to 495 nm). That is, in the present modification example, the period of the unevenness 320 is made shorter as the wavelength of the light detected by the imaging element 100 becomes shorter.

In the present modification example, since the period of the unevenness 320 is set to be close to the wavelength according to the wavelength of light, a scattering effect of light by the unevenness 320 can be suitably extracted, an effect of controlling reflection can be improved. Note that although not illustrated in FIG. 8, in a case of an imaging element 100 that detects infrared light (for example, a wavelength being 800 nm or more), a period of unevenness 320 on a side surface of a pixel isolation portion 304 thereof is preferably longer than the period of the unevenness 320 on the side surface of the pixel isolation portion 304 of the imaging element 100R that detects the red light.

Furthermore, as illustrated in FIG. 9, even in a case where the period of the unevenness 320 of the pixel isolation portion 304 is changed according to the wavelength of light detected by the imaging element 100, the length of the pixel isolation portion 304 along the thickness of the semiconductor substrate 300 may be substantially the same in the imaging elements 100R, 100G, and 100B.

Alternatively, as illustrated in FIG. 10, in a case where the period of the unevenness 320 of the pixel isolation portion 304 is changed according to the wavelength of light detected by the imaging element 100, the length of the pixel isolation portion 304 along the thickness of the semiconductor substrate 300 may be changed according to the wavelength of light detected by the imaging element 100.

Specifically, the length in the thickness direction of the semiconductor substrate 300 of the pixel isolation portion 304 of the imaging element 100R that detects the red light (for example, the wavelength being 620 nm to 750 nm) is shorter than the length in the thickness direction of the semiconductor substrate 300 of the pixel isolation portion 304 of the imaging element 100G that detects the green light (for example, the wavelength being 495 nm to 570 nm). Furthermore, the length in the thickness direction of the semiconductor substrate 300 of the pixel isolation portion 304 of the imaging element 100G that detects the green light is shorter than the length in the thickness direction of the semiconductor substrate 300 of the pixel isolation portion 304 of the imaging element 100B that detects the blue light (for example, the wavelength being 450 nm to 495 nm).

In other words, a distance r from an upper surface of the pixel isolation portion 304 of the imaging element 100R that detects the red light to the light receiving surface 300a is longer than a distance g from an upper surface of the pixel isolation portion 304 of the imaging element 100G that detects the green light to the light receiving surface 300a. Furthermore, the distance g from the upper surface of the pixel isolation portion 304 of the imaging element 100G that detects the green light to the light receiving surface 300a is longer than a distance b from an upper surface of the pixel isolation portion 304 of the imaging element 100B that detects the blue light to the light receiving surface 300a.

Since the light reaches a deeper portion of the semiconductor substrate 300 as the wavelength thereof becomes longer, it is possible to control reflection of the light on the side surface of the pixel isolation portion 304 by changing the length of the pixel isolation portion 304 as described above. Note that although not illustrated in FIG. 10, the length of the pixel isolation portion 304 of the imaging element 100 that detects the infrared light (for example, the wavelength being 800 nm or more) is preferably shorter than the length of the pixel isolation portion 304 of the imaging element 100R that detects the red light.

### 4. Second Embodiment

### 4.1 Background

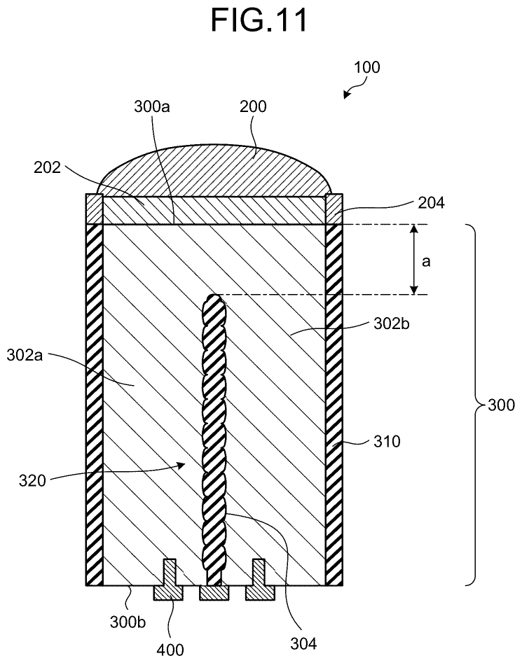

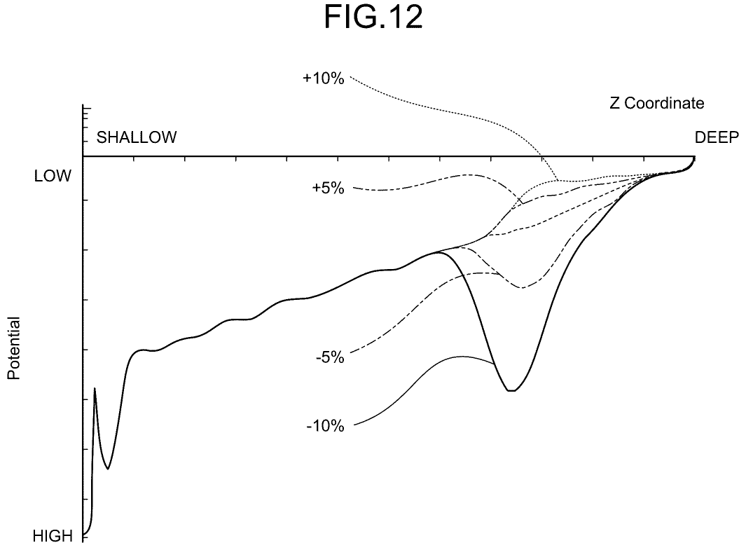

Next, the second embodiment of the present disclosure created by the present inventors will be described. First, a background in which the present inventors have created the second embodiment will be described with reference to FIG. 11 and FIG. 12. FIG. 11 and FIG. 12 are explanatory diagrams for describing the present embodiment.

FIG. 12 is a graph illustrating a change in potential with respect to a depth (Z) starting from a light receiving surface 300a at a center of an imaging element 100 in a semiconductor substrate 300. According to FIG. 12, it can be seen that the potential changes sensitively as a distance from an upper surface of a pixel isolation portion 304 to the light receiving surface 300a (length 0 illustrated in FIG. 11) changes to +10%, +5%, −5%, and −10% with respect to a median. Then, when the potential changes sensitively in such a manner, charge transfer and isolation ratio characteristics between pixels 302a and 302b greatly change. Specifically, since the potential becomes low in a case where the length a is longer than the median, it becomes difficult to isolate the pixels 302a and 302b. Furthermore, since the potential becomes high in a case where the length a is shorter than the median, transfer between the pixels 302a and 302b becomes difficult.

However, it has been difficult to accurately form the pixel isolation portion 304, and variations in the length of the pixel isolation portion 304 have been inevitable. Thus, it has been difficult to prevent generation of variations in the charge transfer and the isolation ratio characteristics between the pixels 302a and 302b.

Thus, in view of such a situation, the present inventors have created the second embodiments of the present disclosure described below.

### 4.2 Detailed Configuration

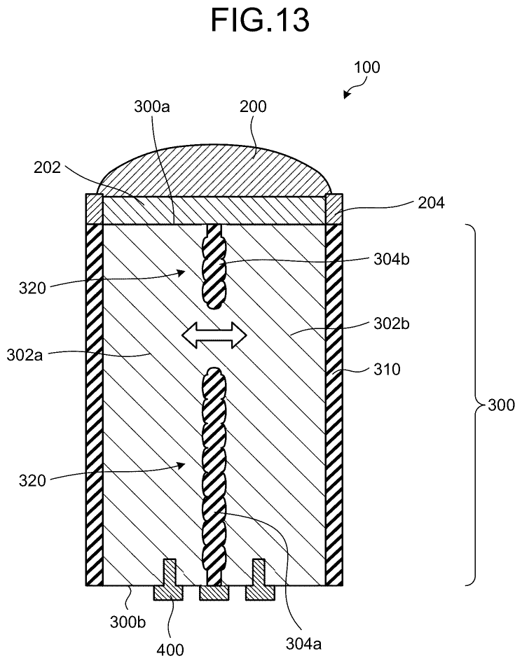

First, a detailed configuration of an imaging element 100 according to the second embodiment of the present disclosure will be described with reference to FIG. 13. FIG. 13 is a schematic diagram of a cross section of the imaging element 100 according to the second embodiment of the present disclosure, and is specifically a schematic diagram of a cross section of the imaging element 100 cut in a thickness direction of a semiconductor substrate 300. Note that illustration of a diffusion region 306 is omitted in FIG. 13 for easy understanding. In addition, in the following description, an element common with the first embodiment and the comparative example is denoted by a common reference sign in the drawing, and description thereof will be omitted.

In the present embodiment, as illustrated in FIG. 13, a pixel isolation portion 304 that isolates two pixels 302a and 302b from each other includes, in a thickness direction of the semiconductor substrate 300, an isolation portion (first isolation portion) 304b provided in such a manner as to penetrate a part of the semiconductor substrate 300 from a light receiving surface 300a, and an isolation portion (second isolation portion) 304a provided in such a manner as to penetrate a part of the semiconductor substrate 300 from a surface 300b facing the light receiving surface 300a. In the present embodiment, since the pixel isolation portion 304 includes the isolation portion 304b extending from the light receiving surface 300a and the isolation portion 304a extending from the surface 300b, it is possible to form the pixel isolation portion 304 while controlling variations in the length in the thickness direction of the semiconductor substrate 300. As a result, in the present embodiment, it is possible to control variations in charge transfer and isolation ratio characteristics between the pixels 302a and 302b.

Furthermore, also in the present embodiment, the isolation portions 304a and 304b are preferably formed of a high refractive index material. In the present embodiment, since the isolation portions 304a and 304b are formed of such a high refractive index material, a difference in a refractive index from the semiconductor substrate 300 can be reduced, and reflection on surfaces of the isolation portions 304a and 304b can be controlled.

In addition, also in the present embodiment, side surfaces of the isolation portions 304a and 304b include uneven surfaces having unevenness 320, as illustrated in FIG. 13. In the present embodiment, since the side surfaces of the isolation portions 304a and 304b include the surfaces having the unevenness 320, light is scattered by the unevenness 320. Thus, specular reflection intensity on the side surfaces of the isolation portions 304a and 304b is reduced, and so-called reflection can be controlled. Specifically, as illustrated in FIG. 13, the unevenness 320 of the pixel isolation portion 304 has a hemispherical protrusion. Note that in the present embodiment, the unevenness 320 is not limited to the hemispherical shape, and may have a conical or pyramidal protrusion.

Note that also in the present embodiment, similarly to the second modification example of the first embodiment, a period of the unevenness 320 of the pixel isolation portion 304 may be changed according to a wavelength of light detected by the imaging element 100.

Furthermore, in the present embodiment, as illustrated in FIG. 13, a diffusion region (not illustrated) is formed above the isolation portion 304a (on a side of the light receiving surface 300a) and below the isolation portion 304b (on a side of the surface 300b) by introduction of an impurity of a first conductive type (such as an n-type), for example, by ion implantation. The diffusion region can function as an overflow path (indicated by an arrow in FIG. 13) capable of exchanging generated charge between the pixels 302a and 302b. Note that the imaging element 100 according to the present embodiment is not limited to the configuration illustrated in FIG. 13.

Furthermore, the imaging element 100 according to the present embodiment can be formed as follows. First, similarly to the first embodiment, a trench penetrating a part of the semiconductor substrate 300 from the surface 300b of the semiconductor substrate 300 in the thickness direction of the semiconductor substrate 300 is formed. At this time, the trench is formed in such a manner that a side surface of the trench is uneven. Then, a high refractive material is embedded in the trench, whereby the isolation portion 304a is formed.

Then, the diffusion region (not illustrated) serving as the overflow path is formed in a region of the semiconductor substrate 300 above the isolation portion 304a (on the side of the light receiving surface) by introduction of the impurity of the first conductive type (such as the n-type), for example, by the ion implantation.

Then, a length of the isolation portion 304a is measured, and a length of the isolation portion 304b is determined on the basis of a measurement result. Furthermore, in a region of the semiconductor substrate 300 on the side of the light receiving surface of the isolation portion 304a, the trench penetrating a part of the semiconductor substrate 300 from the light receiving surface 300a of the semiconductor substrate 300 in the thickness direction of the semiconductor substrate 300 is formed with alignment being performed in such a manner as to overlap with the isolation portion 304a. At this time, the trench is formed in such a manner that a side surface of the trench is uneven. Then, the isolation portion 304b is formed by embedding of the high refractive material in the trench.

As described above, since the isolation portion 304a is formed first and the isolation portion 304b is formed on the basis of the length of the isolation portion 304a, it is possible to form the entire pixel isolation portion 304 while controlling the variations in the length thereof in the thickness direction of the semiconductor substrate 300. As a result, in the present embodiment, it is possible to control variations in charge transfer and isolation ratio characteristics between the pixels 302a and 302b.

### 4.3 Modification Example

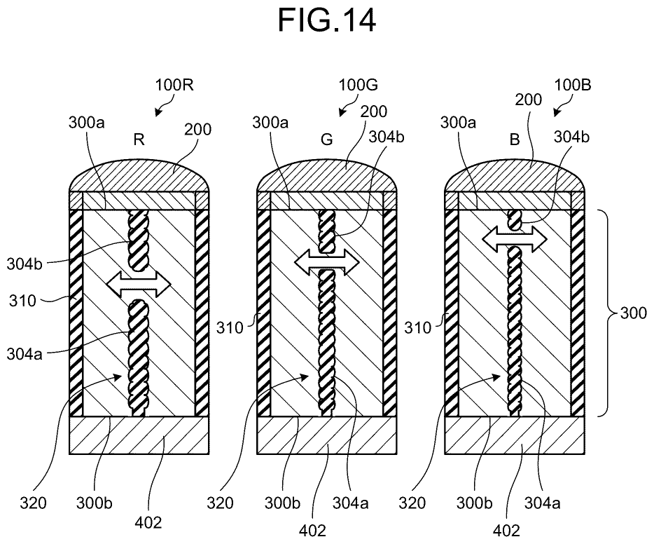

Furthermore, in the present embodiment, the lengths of the isolation portions 304a and 304b along the thickness of the semiconductor substrate 300 may be changed according to a wavelength of light detected by the imaging element 100. Thus, a configuration of such an imaging element 100 according to a modification example of the present embodiment will be described with reference to FIG. 14. FIG. 14 is a schematic diagram of a cross section of the imaging element 100 according to the modification example of the second embodiment of the present disclosure, and is specifically a schematic diagram of a cross section of the imaging element 100 cut in a thickness direction of a semiconductor substrate 300. Note that illustration of a diffusion region 306 is omitted in FIG. 14 for easy understanding. In addition, in the following description, an element common with the first embodiment and the comparative example is denoted by a common reference sign in the drawing, and description thereof will be omitted.

Specifically, as illustrated in FIG. 14, a length in a thickness direction of a semiconductor substrate 300 of an isolation portion 304a of an imaging element 100R that detects red light (for example, a wavelength being 620 nm to 750 nm) is shorter than a length in the thickness direction of the semiconductor substrate 300 of an isolation portion 304a of an imaging element 100G that detects green light (for example, a wavelength being 495 nm to 570 nm). The length in the thickness direction of the semiconductor substrate 300 of the isolation portion 304a of the imaging element 100G that detects the green light is shorter than a length in the thickness direction of the semiconductor substrate 300 of an isolation portion 304a of an imaging element 100B that detects blue light (for example, a wavelength being 450 nm to 495 nm). Furthermore, as illustrated in FIG. 14, a length in the thickness direction of the semiconductor substrate 300 of an isolation portion 304b of the imaging element 100R that detects the red light is longer than a length in the thickness direction of the semiconductor substrate 300 of an isolation portion 304b of the imaging element 100G that detects the green light (for example, the wavelength being 495 nm to 570 nm). The length in the thickness direction of the semiconductor substrate 300 of the isolation portion 304b of the imaging element 100G that detects the green light is longer than a length in the thickness direction of the semiconductor substrate 300 of an isolation portion 304b of the imaging element 100B that detects the blue light (for example, the wavelength being 450 nm to 495 nm).

In the present embodiment, when the lengths of the isolation portions 304a and 304b of each of the imaging elements 100R, 100G, and 100B are set in the manner described above, a slit (specifically, an overflow path) (indicated by an arrow in FIG. 14) in which the isolation portions 304a and 304b face each other can be set at a deeper place of the semiconductor substrate 300 as the imaging element 100 detects light having a longer wavelength. Since light having a longer wavelength reaches a deeper portion of the semiconductor substrate 300, according to the present embodiment, it is possible to control reflection of the light on side surfaces of the isolation portions 304a and 304b by changing the position of the slit according to the wavelength of the light detected by the imaging element 100. Note that although not illustrated in FIG. 14, a slit between isolation portions 304a and 304b of an imaging element 100 that detects infrared light (for example, a wavelength being 800 nm or more) is preferably located at a deeper portion than the slit between the isolation portions 304a and 304b of the imaging element 100R that detects the red light.

### 5. Third Embodiment

### 5.1 Detailed Configuration

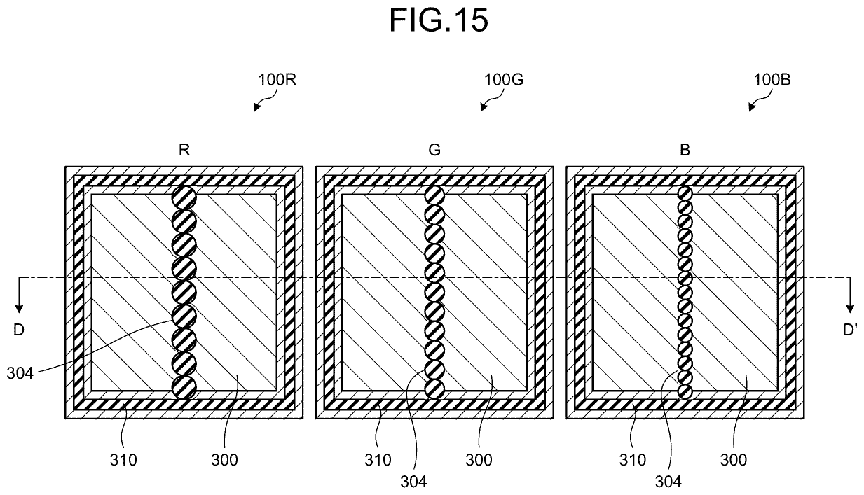

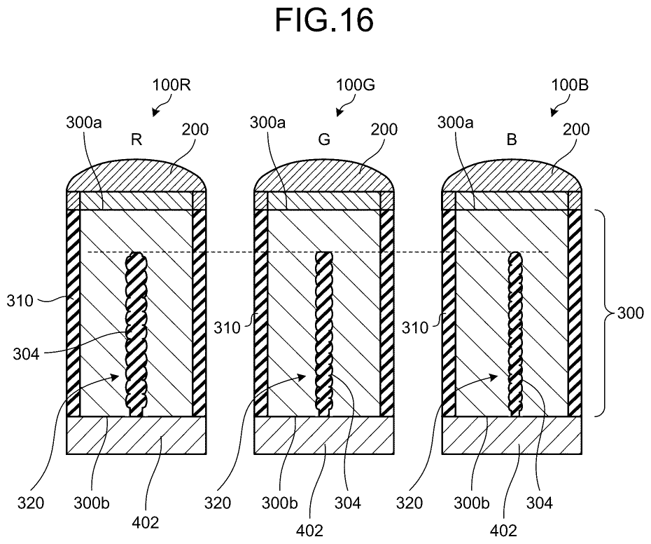

Next, a detailed configuration of an imaging element 100 according to the third embodiment of the present disclosure will be described with reference to FIG. 15 to FIG. 18. FIG. 15 is a schematic diagram of a cross section of the imaging element 100 according to the third embodiment of the present disclosure, and is specifically a schematic diagram of a cross section of the imaging element 100 cut along a plane of a semiconductor substrate 300. FIG. 16 to FIG. 18 are schematic diagrams of a cross section of the imaging element 100 according to the third embodiment of the present disclosure, and specifically are schematic diagrams of a cross section of the imaging element 100 cut in a thickness direction of the semiconductor substrate 300, that is, a cross section of the semiconductor substrate 300 cut along a line D-D′ illustrated in FIG. 15. Note that illustration of a diffusion region 306 or a part thereof is omitted in FIG. 15 to FIG. 18 for easy understanding. In addition, in the following description, an element common with the first embodiment and the comparative example is denoted by a common reference sign in the drawings, and description thereof will be omitted.

In the first embodiment described above, as illustrated in FIG. 4, the pixel isolation portion 304 is provided in the vicinity of the center of the imaging element 100 in such a manner as to extend in the up-down direction in the drawing. On the other hand, in the present embodiment, as illustrated in FIG. 15, a pixel isolation portion 304 is provided in such a manner as to extend from an end of the imaging element 100 in an up-down direction of the drawing.

Furthermore, in the first embodiment described above, the side surface of the pixel isolation portion 304 has the unevenness 320 having a protrusion having a hemispherical shape or the like. However, in the present embodiment, as illustrated in FIG. 15, the pixel isolation portion 304 itself has a shape in which a plurality of circles are continuous in a plan view. In the present embodiment, since the pixel isolation portion 304 has such a shape, reflection can be further reduced.

Furthermore, also in the present embodiment, as illustrated in FIG. 15, a size (diameter) of the circles included in the pixel isolation portion 304 may be changed according to a wavelength of light detected by the imaging element 100. Specifically, as illustrated in FIG. 15, a size of circles of a pixel isolation portion 304 of an imaging element 100R that detects red light (for example, a wavelength being 620 nm to 750 nm) is larger than a size of circles of a pixel isolation portion 304 of an imaging element 100G that detects green light (for example, a wavelength being 495 nm to 570 nm). Furthermore, the size of the circles of the pixel isolation portion 304 of the imaging element 100G that detects the green light is larger than a size of circles of a pixel isolation portion 304 of the imaging element 100G that detects blue light (for example, a wavelength being 450 nm to 495 nm).

In the present embodiment, by making the size (diameter) of the circles included in the pixel isolation portion 304 close to the wavelength, it is possible to suitably extract a light scattering effect due to unevenness of the pixel isolation portion 304, and to improve the effect of controlling reflection. Note that although not illustrated in FIG. 15, in a case of an imaging element 100 that detects infrared light (for example, a wavelength being 800 nm or more), a size of circles included in a pixel isolation portion 304 thereof is preferably larger than the size of the circles included in the pixel isolation portion 304 of the imaging element 100R that detects the red light.

Furthermore, as illustrated in FIG. 16, even in a case where the size of the circles included in the pixel isolation portion 304 is changed according to the wavelength of light detected by the imaging element 100, a length of the pixel isolation portion 304 along the thickness of the semiconductor substrate 300 may be substantially the same in the imaging elements 100R, 100G, and 100B.

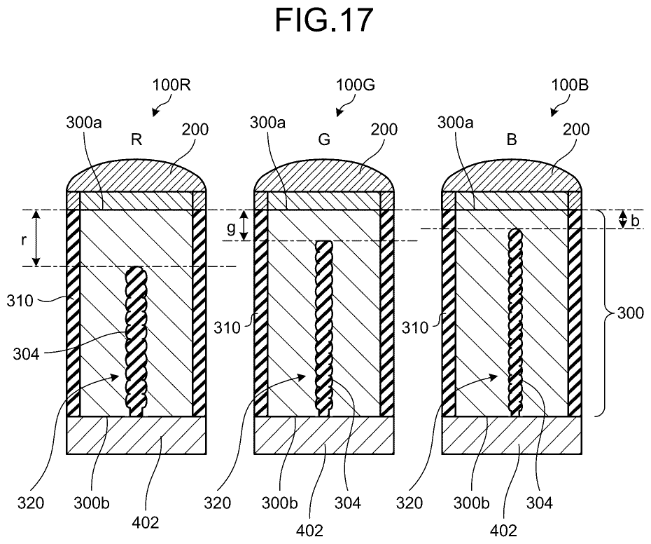

Alternatively, as illustrated in FIG. 17, in a case where the size of the circles included in the pixel isolation portion 304 is changed according to the wavelength of the light detected by the imaging element 100, the length of the pixel isolation portion 304 along the thickness of the semiconductor substrate 300 may be changed according to the wavelength of the light detected by the imaging element 100.

Specifically, the length in the thickness direction of the semiconductor substrate 300 of the pixel isolation portion 304 of the imaging element 100R that detects the red light (for example, the wavelength being 620 nm to 750 nm) is shorter than the length in the thickness direction of the semiconductor substrate 300 of the pixel isolation portion 304 of the imaging element 100G that detects the green light (for example, the wavelength being 495 nm to 570 nm). Furthermore, the length in the thickness direction of the semiconductor substrate 300 of the pixel isolation portion 304 of the imaging element 100G that detects the green light is shorter than the length in the thickness direction of the semiconductor substrate 300 of the pixel isolation portion 304 of the imaging element 100B that detects the blue light (for example, the wavelength being 450 nm to 495 nm).

In other words, a distance r from an upper surface of the pixel isolation portion 304 of the imaging element 100R that detects the red light to a light receiving surface 300a is longer than a distance g from an upper surface of the pixel isolation portion 304 of the imaging element 100G that detects the green light to a light receiving surface 300a. Furthermore, the distance g from the upper surface of the pixel isolation portion 304 of the imaging element 100G that detects the green light to the light receiving surface 300a is longer than a distance b from an upper surface of the pixel isolation portion 304 of the imaging element 100B that detects the blue light to a light receiving surface 300a.

Since the light reaches a deeper portion of the semiconductor substrate 300 as the wavelength thereof becomes longer, it is possible to control reflection of the light on the side surface of the pixel isolation portion 304 by changing the length of the pixel isolation portion 304 as described above. Note that although not illustrated in FIG. 17, the length of the pixel isolation portion 304 of the imaging element 100 that detects the infrared light (for example, the wavelength being 800 nm or more) is preferably shorter than the length of the pixel isolation portion 304 of the imaging element 100R that detects the red light.

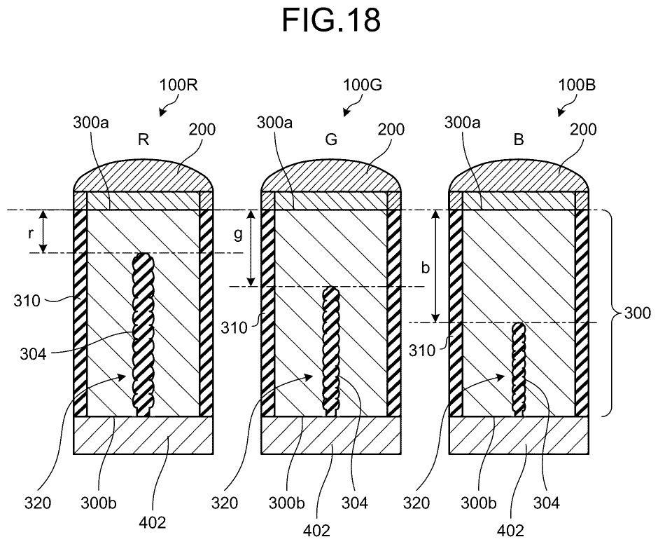

Alternatively, as illustrated in FIG. 18, the length in the thickness direction of the semiconductor substrate 300 of the pixel isolation portion 304 of the imaging element 100R that detects the red light (for example, the wavelength being 620 nm to 750 nm) may be made longer than the length in the thickness direction of the semiconductor substrate 300 of the pixel isolation portion 304 of the imaging element 100G that detects the green light (for example, the wavelength being 495 nm to 570 nm). Furthermore, the length in the thickness direction of the semiconductor substrate 300 of the pixel isolation portion 304 of the imaging element 100G that detects the green light may be made longer than the length in the thickness direction of the semiconductor substrate 300 of the pixel isolation portion 304 of the imaging element 100B that detects the blue light (for example, the wavelength being 450 nm to 495 nm). In other words, as illustrated in the example in FIG. 18, a distance r from the upper surface of the pixel isolation portion 304 of the imaging element 100R that detects red light to the light receiving surface 300a is shorter than a distance g from the upper surface of the pixel isolation portion 304 of the imaging element 100G that detects green light to the light receiving surface 300a. Furthermore, the distance g from the upper surface of the pixel isolation portion 304 of the imaging element 100G that detects the green light to the light receiving surface 300a is shorter than the distance b from the upper surface of the pixel isolation portion 304 of the imaging element 100B that detects the blue light to the light receiving surface 300a. Note that although not illustrated in FIG. 18, compared to the length of the pixel isolation portion 304 of the imaging element 100R that detects the red light, that of the imaging element 100 that detects the infrared light (for example, the wavelength being 800 nm or more) may be made long.

Note that the imaging element 100 according to the present embodiment is not limited to the configuration illustrated in FIG. 15 to FIG. 18.

### 5.2 First Modification Example

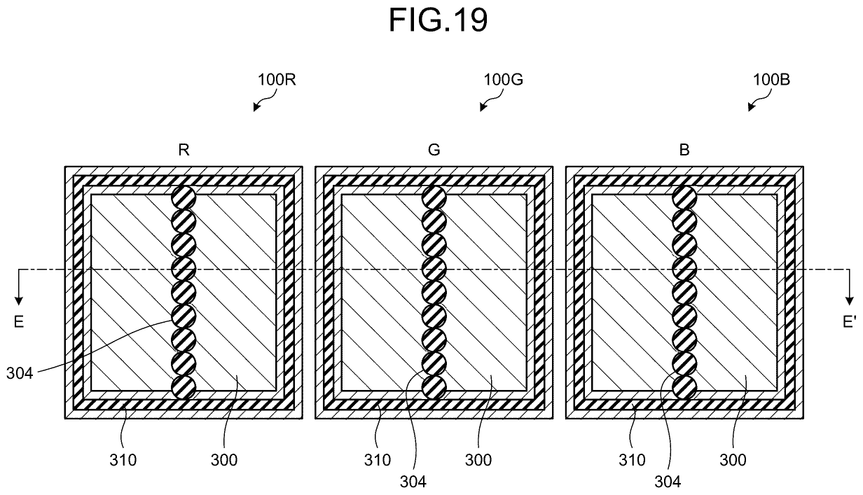

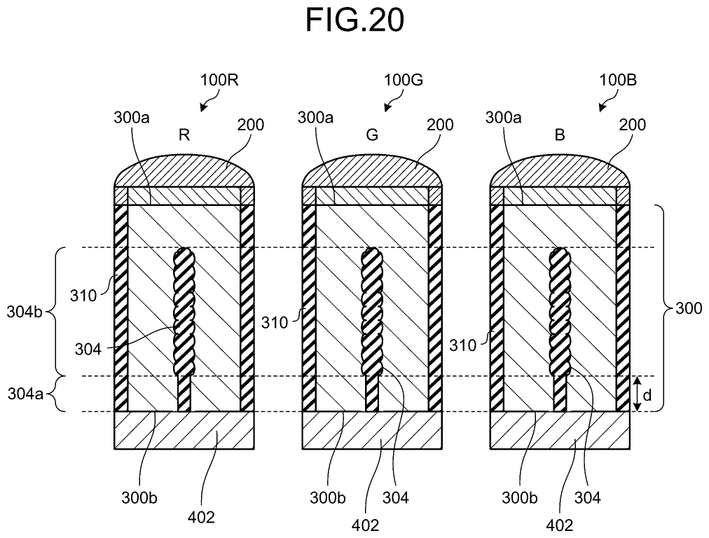

First, a detailed configuration of an imaging element 100 according to the first modification example of the third embodiment of the present disclosure will be described with reference to FIG. 19 and FIG. 20. FIG. 19 is a schematic diagram of a cross section of the imaging element 100 according to the first modification example of the third embodiment of the present disclosure, and is specifically a schematic diagram of a cross section of the imaging element 100 cut along a plane of a semiconductor substrate 300. FIG. 20 is a schematic diagram of a cross section of the imaging element 100 according to the first modification example of the third embodiment of the present disclosure, and specifically is a schematic diagram of a cross section of the imaging element 100 cut in a thickness direction of the semiconductor substrate 300, that is, a cross section of the semiconductor substrate 300 cut along a line E-E′ illustrated in FIG. 19. Note that illustration of a diffusion region 306 or a part thereof is omitted in FIG. 19 and FIG. 20 for easy understanding. In addition, in the following description, an element common with the first embodiment and the comparative example is denoted by a common reference sign in the drawings, and description thereof will be omitted.

In the present modification example, as illustrated in FIG. 19, a pixel isolation portion 304 itself has a shape in which a plurality of circles is continuous in a plan view. A size of the circles included in the pixel isolation portion 304 is substantially the same in any of the imaging elements 100R, 100G, and 100B.

Furthermore, in the present modification example, as illustrated in FIG. 20, the pixel isolation portion 304 includes an isolation portion (first isolation portion) 304a provided in such a manner as to penetrate a part of the semiconductor substrate 300 from a surface 300b in the thickness direction of the semiconductor substrate 300, and an isolation portion (second isolation portion) 304b provided in such a manner as to penetrate a part of the semiconductor substrate 300 in the thickness direction of the semiconductor substrate 300 from the isolation portion (first isolation portion) 304a toward a light receiving surface 300a. Furthermore, in the present modification example, a side surface of the isolation portion 304a is flat, and a side surface of the isolation portion 304b has hemispherical unevenness 320. In addition, a length d of the isolation portion 304a on a side of the surface 300b is preferably about 200 nm.

In the present modification example, it is possible to control reflection on the side surface by making the side surface of the pixel isolation portion 304 uneven up to a depth at which light incident from the light receiving surface 300a may reach. Furthermore, in the present modification example, since the side surface of the pixel isolation portion 304 is made flat at a depth at which the light is less likely to reach, it is possible to make it easy to form a trench to be the pixel isolation portion 304.

Furthermore, in this case, as illustrated in FIG. 20, the length of the entire pixel isolation portion 304 along the thickness of the semiconductor substrate 300 of each of the imaging elements 100R, 100G, and 100B may also be substantially the same.

### 5.3 Second Modification Example

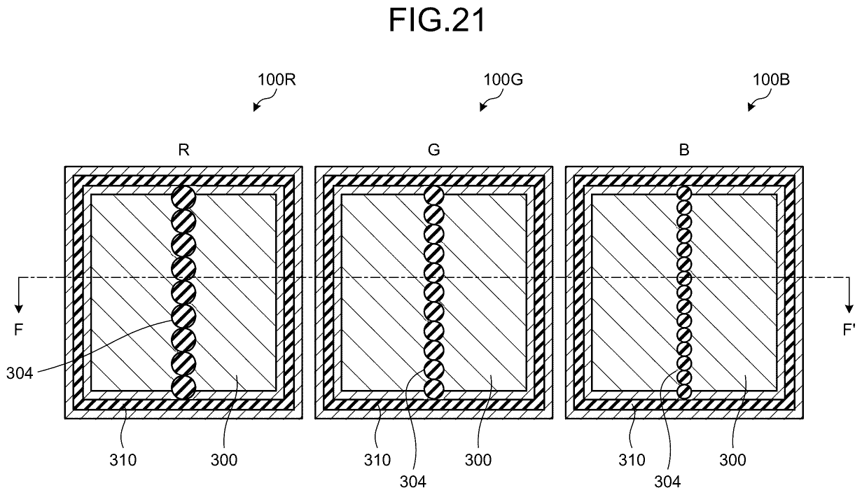

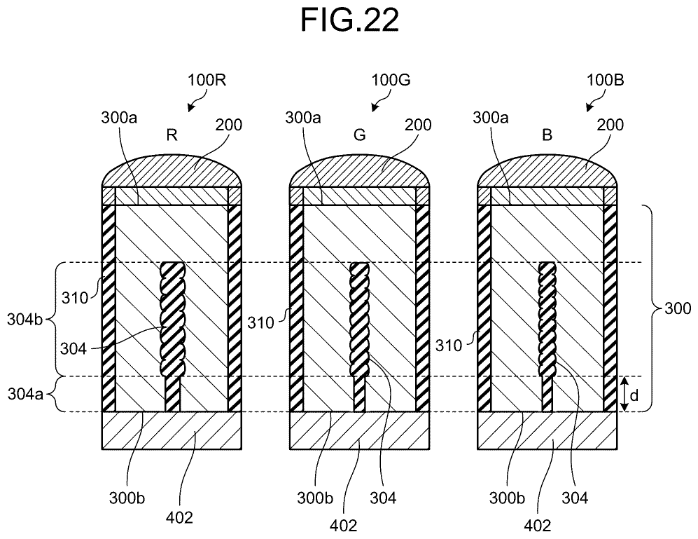

First, a detailed configuration of an imaging element 100 according to the second modification example of the third embodiment of the present disclosure will be described with reference to FIG. 21 to FIG. 24. FIG. 21 is a schematic diagram of a cross section of the imaging element 100 according to the second modification example of the third embodiment of the present disclosure, and is specifically a schematic diagram of a cross section of the imaging element 100 cut along a plane of a semiconductor substrate 300. FIG. 22 to FIG. 24 are schematic diagrams of a cross section of the imaging element 100 according to the second modification example of the third embodiment of the present disclosure, and specifically are schematic diagrams of a cross section of the imaging element 100 cut in a thickness direction of the semiconductor substrate 300, that is, a cross section of the semiconductor substrate 300 cut along a line F-F′ illustrated in FIG. 21. Note that illustration of a diffusion region 306 or a part thereof is omitted in FIG. 21 to FIG. 24 for easy understanding. In addition, in the following description, an element common with the first embodiment and the comparative example is denoted by a common reference sign in the drawings, and description thereof will be omitted.

In the present modification example, similarly to the present embodiment, as illustrated in FIG. 21, a size of circles included in a pixel isolation portion 304 may be changed according to a wavelength of light detected by the imaging element 100. Furthermore, in the example of FIG. 21, as illustrated in FIG. 22, the pixel isolation portion 304 may include an isolation portion 304a provided in such a manner as to penetrate a part of the semiconductor substrate 300 from a surface 300b in the thickness direction of the semiconductor substrate 300, and an isolation portion 304b provided in such a manner as to penetrate a part of the semiconductor substrate 300 in the thickness direction of the semiconductor substrate 300 from the isolation portion 304a toward a light receiving surface 300a. Furthermore, as illustrated in FIG. 21, an entire length of a pixel isolation portion 304 along a thickness of a semiconductor substrate 300 of each of imaging elements 100R, 100G, and 100B may also be substantially the same.

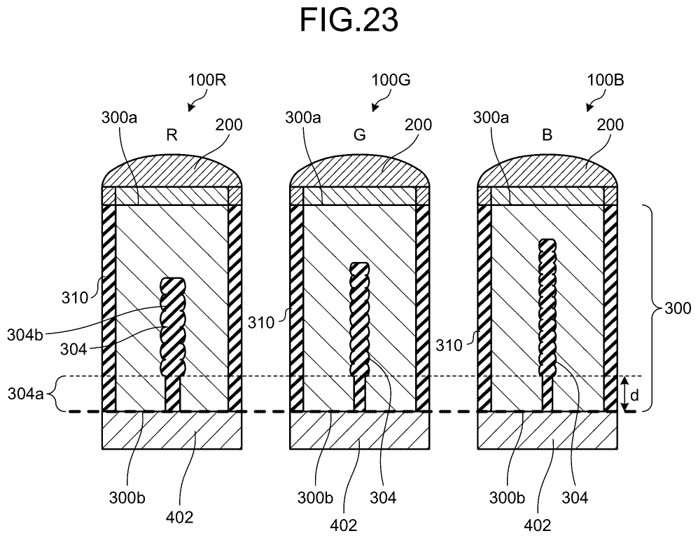

Alternatively, as illustrated in FIG. 23, a length of the isolation portion 304b along the thickness of the semiconductor substrate 300 may be also changed according to the wavelength of light detected by the imaging element 100. Specifically, a length in the thickness direction of the semiconductor substrate 300 of an isolation portion 304b of the imaging element 100R that detects red light (for example, a wavelength being 620 nm to 750 nm) may be made shorter than a length in the thickness direction of the semiconductor substrate 300 of an isolation portion 304b of the imaging element 100G that detects green light (for example, a wavelength being 495 nm to 570 nm). Furthermore, the length in the thickness direction of the semiconductor substrate 300 of the isolation portion 304b of the imaging element 100G that detects the green light may be made shorter than a length in the thickness direction of the semiconductor substrate 300 of an isolation portion 304b of the imaging element 100B that detects blue light (for example, a wavelength being 450 nm to 495 nm). In the present modification example, in the above manner, the distance from the light receiving surface 300a of the isolation portion 304b becomes longer as the wavelength of the detected light is longer. Then, since the light having the longer wavelength reaches a deeper portion of the semiconductor substrate 300, it is possible to control reflection of the light on a side surface of the isolation portion 304b in the above manner according to the present modification example.

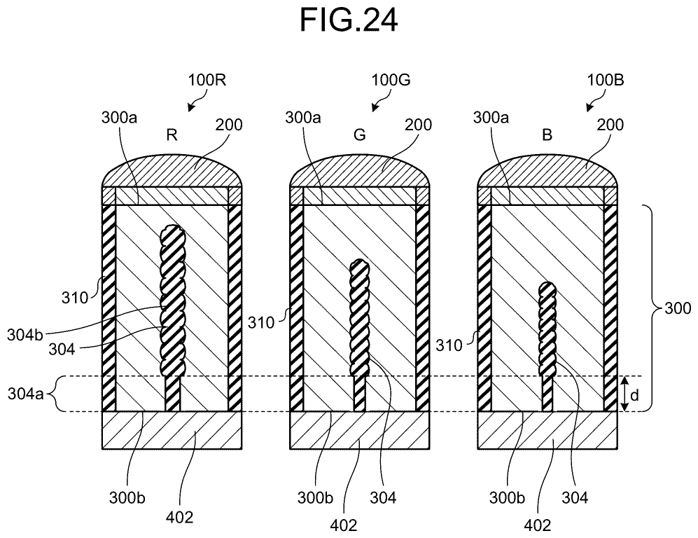

Alternatively, as illustrated in FIG. 24, the length in the thickness direction of the semiconductor substrate 300 of the isolation portion 304b of the imaging element 100R that detects the red light (for example, the wavelength being 620 nm to 750 nm) may be made longer than the length in the thickness direction of the semiconductor substrate 300 of the isolation portion 304b of the imaging element 100G that detects the green light (for example, the wavelength being 495 nm to 570 nm). Furthermore, the length in the thickness direction of the semiconductor substrate 300 of the isolation portion 304b of the imaging element 100G that detects the green light may be made longer than the length in the thickness direction of the semiconductor substrate 300 of the isolation portion 304b of the imaging element 100B that detects the blue light (for example, the wavelength being 450 nm to 495 nm).

### 6. Fourth Embodiment

### 6.1 Background

Next, a fourth embodiment of the present disclosure created by the present inventors will be described. First, a background in which the present inventors have created the fourth embodiment will be described.

In the embodiments described above, an uneven surface is employed as the side surface of the pixel isolation portion 304 in order to reduce reflection on the side surface of the pixel isolation portion 304. However, since the incident light is reflected also on the upper surface of the pixel isolation portion 304 which surface is located on the side of the light receiving surface 300a, deterioration in accuracy of the phase difference detection of the pixels 302a and 302b in the same imaging element 100 and color mixture between the adjacent imaging elements 100 have been generated.

Thus, in view of such a situation, the present inventors have created the fourth embodiment of the present disclosure described below.

In the fourth embodiment created by the present inventors, an uneven surface is employed as an upper surface on a side of a light receiving surface 300a of a pixel isolation portion 304, whereby reflection on the upper surface of the pixel isolation portion 304 is reduced. As a result, according to the present embodiment, it is possible to control deterioration in accuracy of phase difference detection of pixels 302a and 302b in the same imaging element 100 and generation of color mixture between adjacent imaging elements 100.

### 6.2 Detailed Configuration

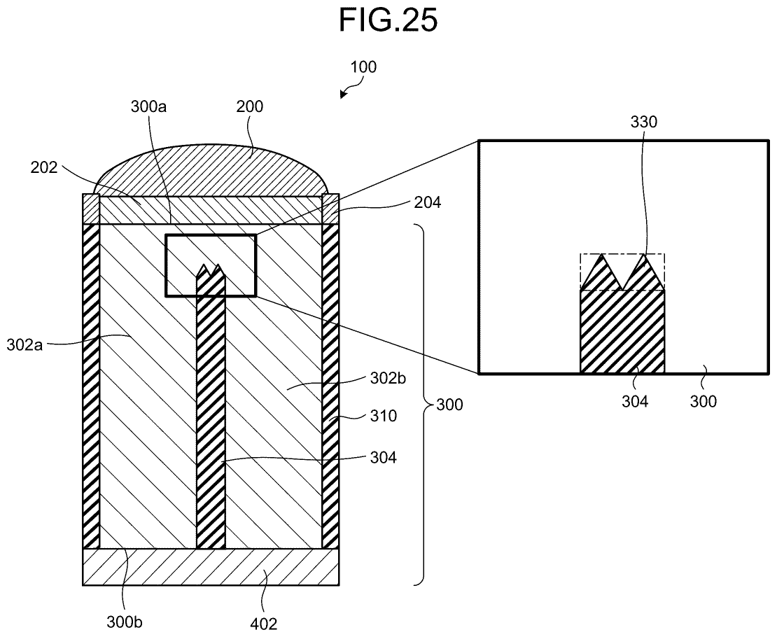

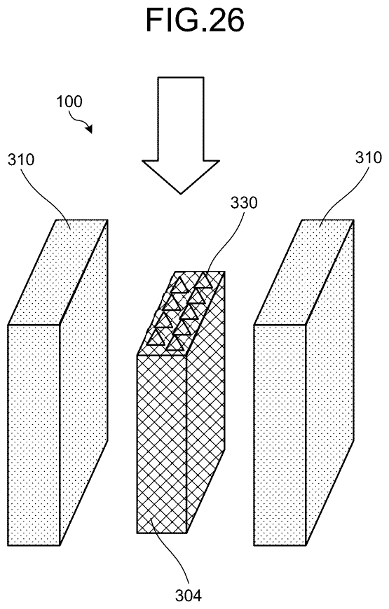

Next, a detailed configuration of an imaging element 100 according to the fourth embodiment of the present disclosure will be described with reference to FIG. 25 and FIG. 26. FIG. 25 is a schematic diagram of a cross section of the imaging element 100 according to the fourth embodiment of the present disclosure, and is specifically a schematic diagram of a cross section of the imaging element 100 cut along a plane of a semiconductor substrate 300 and an enlarged view of a part of the cross section. In addition, FIG. 26 is a perspective view of the imaging element 100 according to the fourth embodiment of the present disclosure. Note that illustration of the diffusion region 306 is omitted in FIG. 25 for easy understanding. In addition, in the following description, an element common with the first embodiment and the comparative example is denoted by a common reference sign in the drawings, and description thereof will be omitted.

In the present embodiment, similarly to the embodiments described above, as illustrated in FIG. 25, a pixel isolation portion 304 that isolates two pixels (photoelectric conversion units (not illustrated)) 302a and 302b includes, as DTI, a groove portion (trench) (not illustrated) provided in such a manner as to penetrate a part of a semiconductor substrate 300 in a thickness direction of the semiconductor substrate 300 from a side of a surface 300b facing a light receiving surface 300a, and a high refractive index material embedded in the trench.

Furthermore, in the present embodiment, as illustrated in FIG. 25 and FIG. 26, an upper surface of the pixel isolation portion 304 includes an uneven surface having a protrusion 330. Specifically, as illustrated in FIG. 25 and FIG. 26, the upper surface of the pixel isolation portion 304 has a pyramidal protrusion 330. Note that in the present embodiment, the protrusion 330 is not limited to the pyramidal shape, and a conical or hemispherical protrusion may be included.

Specifically, in the present embodiment, a region indicated by a broken line in the enlarged view of FIG. 25 has a refractive index that is an average value of a refractive index (B) of the high refractive index material included in the pixel isolation portion 304 and a refractive index (A) of silicon included in the semiconductor substrate 300.

Specifically, reflection is determined by an incident angle and a refractive index difference of a light incident interface. In addition, Fresnel reflection (vertical component) can be expressed by the following expression (1) including the refractive index with respect to incident light intensity I.

$$Fresnel reflection intensity ( vertical component ) = I \times {\{ ( A - B ) / ( A + B ) \}}^{2} \qquad ( 1 )$$

Thus, the region indicated by the broken line has the refractive index that is the average value of the refractive index (B) of the high refractive index material included in the pixel isolation portion 304 and the refractive index (A) of silicon included in the semiconductor substrate 300. Furthermore, since there is a region having a refractive index having an average value of the two between the semiconductor substrate 300 and the pixel isolation portion 304, the difference in refractive index is reduced, and reflection on the upper surface of the pixel isolation portion 304 can be controlled.

Note that a height of the protrusion 330 in the present embodiment is preferably about a several 100 nm, for example. In addition, the imaging element 100 according to the present embodiment is not limited to the configuration illustrated in FIG. 25 and FIG. 26.

### 6.3 Manufacturing Method

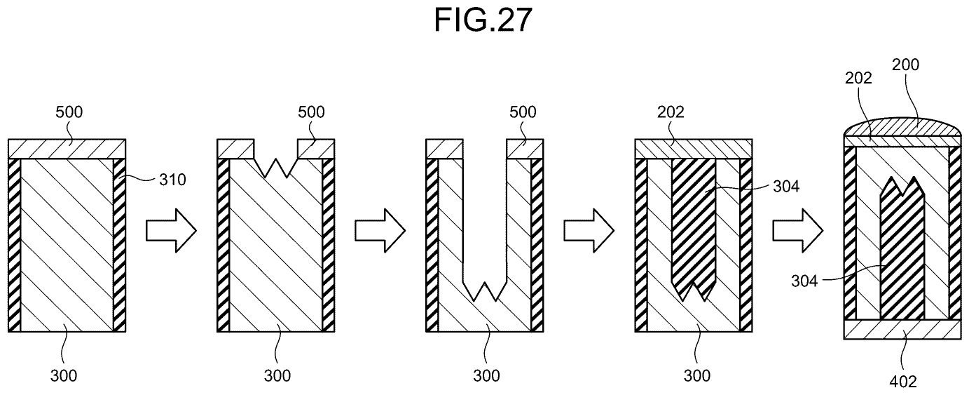

Next, a part of a manufacturing process (manufacturing method) of the imaging element 100 according to the present embodiment will be described with reference to FIG. 27. FIG. 27 is a cross-sectional view for describing a part of the manufacturing process of the manufacturing method of the imaging element 100 according to the present embodiment, and specifically corresponds to the cross-sectional view illustrated in FIG. 25.

First, as illustrated on a left side of FIG. 27, a trench penetrating the semiconductor substrate 300 is formed in the semiconductor substrate 300, and an insulating material is embedded in the trench, whereby an element isolation wall 310 is formed. Furthermore, a mask 500 is formed on a surface of the semiconductor substrate 300.

Next, as illustrated second from the left side of FIG. 27, a pattern is formed on the mask 500 by utilization of a directed self assembly (DSA) material, and the pattern is dry etched, whereby the uneven shape is transferred. The DSA is a method of spontaneously forming a fine pattern having regularity by utilizing a chemical property (phase separation phenomenon) of a polymer or the like. In the DSA, it is possible to easily change a shape or the like of the pattern by changing formulation of the polymer or the like.

Furthermore, as illustrated third from the left side of FIG. 27, when dry etching is further performed along the transferred unevenness, a trench having unevenness at a bottom is formed. Furthermore, by embedding a high refractive material in the trench formed in such a manner, it is possible to form the pixel isolation portion 304 as illustrated fourth from the left side of FIG. 27.

Furthermore, as illustrated on a right side of FIG. 27, a wiring layer 402 including a pixel transistor, a wiring line, and the like is formed on the surface 300b of the semiconductor substrate 300, and a color filter 202 and an on-chip lens 200 are formed on the light receiving surface 300a of the semiconductor substrate 300.

The imaging element 100 according to the present embodiment can be formed in the above manner.

### 6.4 First Modification Example

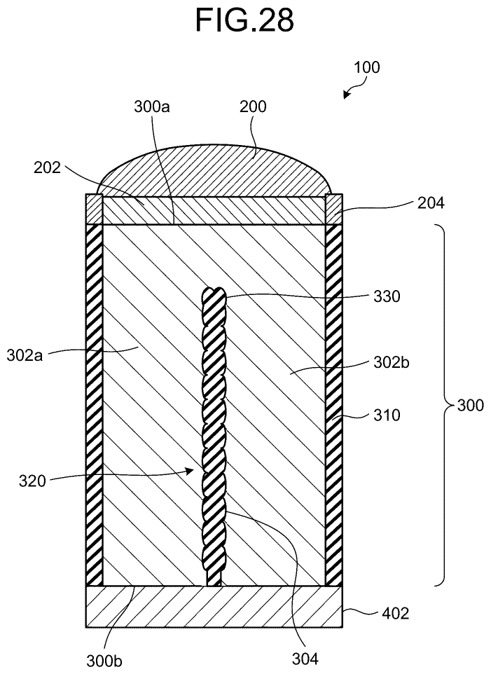

First, a detailed configuration of an imaging element 100 according to the first modification example of the fourth embodiment of the present disclosure will be described with reference to FIG. 28. FIG. 28 is a schematic diagram of a cross section of the imaging element 100 according to the first modification example of the fourth embodiment of the present disclosure, and is specifically a schematic diagram of a cross section of the imaging element 100 cut in a thickness direction of a semiconductor substrate 300. Note that illustration of a diffusion region 306 is omitted in FIG. 28 for easy understanding. In addition, in the following description, an element common with the first embodiment and the comparative example is denoted by a common reference sign in the drawing, and description thereof will be omitted.

As a modification example of the present embodiment, as illustrated in FIG. 28, a protrusion 330 may also be formed on an upper surface of a pixel isolation portion 304 having an uneven side surface as in the embodiment described above.

### 6.5 Second Modification Example

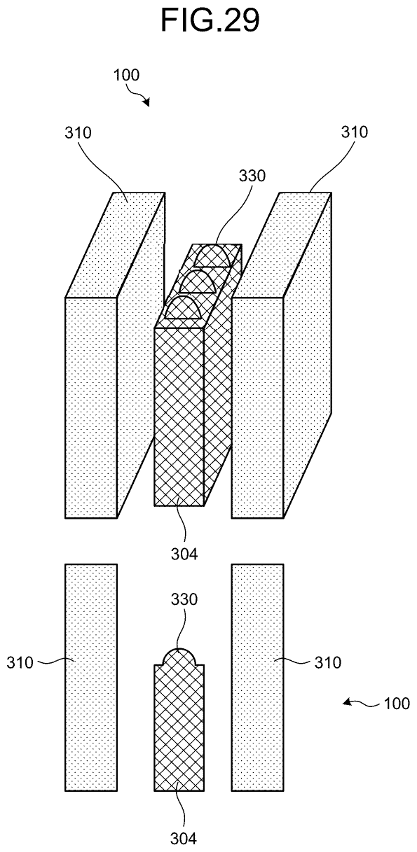

Next, a detailed configuration of an imaging element 100 according to the second modification example of the fourth embodiment of the present disclosure will be described with reference to FIG. 29 to FIG. 31. FIG. 29 to FIG. 31 are explanatory diagrams for describing the detailed configuration of the imaging element 100 according to the second modification example of the fourth embodiment of the present disclosure. Specifically, an upper part of each drawing is a schematic diagram of a cross section of the imaging element 100 cut in a thickness direction of a semiconductor substrate 300, and a lower part is a perspective view of the imaging element 100.

In the present modification example, as illustrated in FIG. 29, an upper surface of a pixel isolation portion 304 may have a hemispherical protrusion 330.

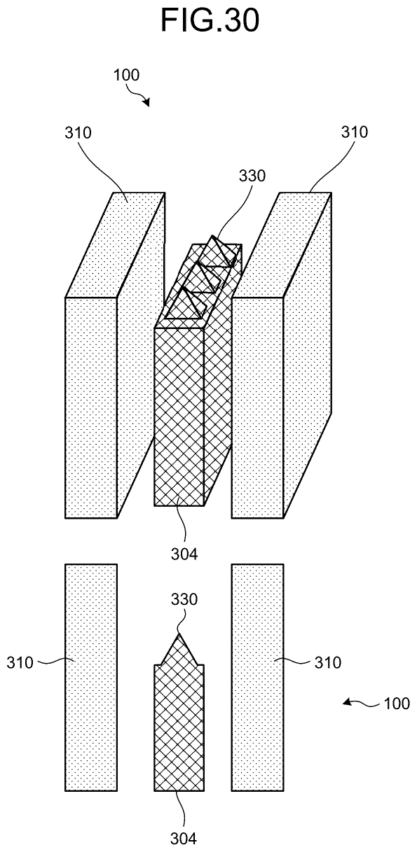

Furthermore, in the present modification example, as illustrated in FIG. 30, an upper surface of a pixel isolation portion 304 may have a pyramidal protrusion 330 provided periodically.

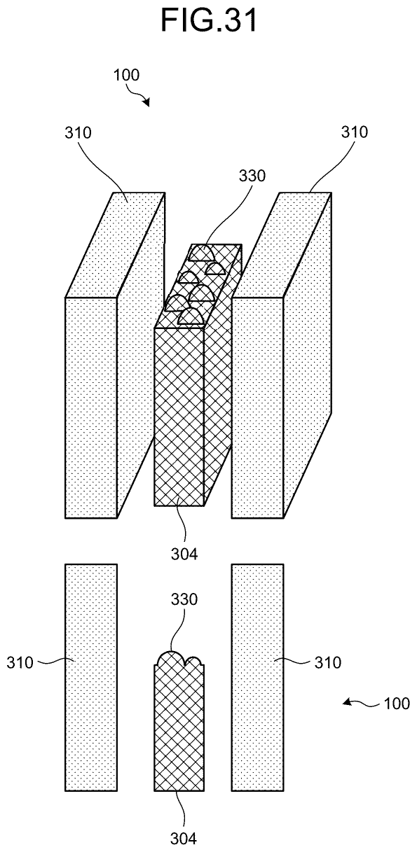

Furthermore, in the present modification example, as illustrated in FIG. 31, an upper surface of a pixel isolation portion 304 may have protrusions 330 randomly provided.

### 7. Conclusion

### <7.1 Conclusion>

As described above, according to the embodiment of the present disclosure, since the side surface of the pixel isolation portion 304 has the unevenness 320, reflection on the side surface of the pixel isolation portion 304 can be controlled. As a result, in the present embodiment, it is possible to control deterioration in accuracy of the phase difference detection of the pixels 302a and 302b in the same imaging element 100 and generation of the color mixture between the adjacent imaging elements 100.

Note that although a case of application to a back-illuminated CMOS image sensor structure has been described in the description of the embodiments of the present disclosure described above, an embodiment of the present disclosure is not limited thereto, and may be applied to another structure.

Note that although the imaging element 100 in which the first conductive type is the n-type, the second conductive type is the p-type, and electrons are used as the signal charge has been described in the embodiments of the present disclosure described above, an embodiment of the present disclosure is not limited to such an example. For example, the present embodiment can be applied to an imaging element 100 in which a first conductive type is a p-type, a second conductive type is an n-type, and holes are used as signal charge.

Furthermore, in the embodiments of the present disclosure described above, the semiconductor substrate 300 is not necessarily a silicon substrate, and may be another substrate (such as a silicon on insulator (SOI) substrate, an SiGe substrate, or the like). In addition, the semiconductor substrate 300 may be obtained by forming of a semiconductor structure or the like on such various substrates.

Furthermore, the imaging device 1 according to the embodiments of the present disclosure is not limited to an imaging device that detects a distribution of an amount of incident light of visible light and captures the distribution as an image. For example, the present embodiment can be applied to an imaging device that captures a distribution of an incident amount of infrared rays, X-rays, particles, or the like as an image, or an imaging device (physical quantity distribution detection device) such as a fingerprint detection sensor that detects a distribution of other physical quantities such as pressure and capacitance and captures the distribution as an image.

Furthermore, the imaging device 1 according to the embodiments of the present disclosure can be manufactured by utilization of a method, device, and condition used for manufacturing of a general semiconductor device. That is, the imaging device 1 according to the present embodiment can be manufactured by utilization of an existing semiconductor device manufacturing process.

Note that examples of the above-described method include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (such as a magnetron sputtering method, a radio frequency (RF)-direct current (DC) coupled bias sputtering method, an electron cyclotron resonance (ECR) sputtering method, a facing target sputtering method, and a radio frequency sputtering method), an ion plating method, a laser ablation method, a molecular beam epitaxy (MBE) method, and a laser transfer method. Examples of the CVD method include a plasma CVD method, a thermal CVD method, a metal organic (MO) CVD method, and a photo-CVD method. Furthermore, other methods include an electrolytic plating method, an electroless plating method, a spin coating method; an immersion method; a casting method; a micro-contact printing method; a drop casting method; various printing methods such as a screen printing method, an inkjet printing method, an offset printing method, a gravure printing method, and a flexographic printing method; a stamping method; a spraying method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calender coater method. Furthermore, examples of the patterning method include shadow masking, a laser transfer, chemical etching such as photolithography, and physical etching using an ultraviolet ray, a laser, or the like. In addition, examples of a planarization technique include a chemical mechanical polishing (CMP) method, a laser planarization method, a reflow method, and the like.

### <7.2 Other Forms>

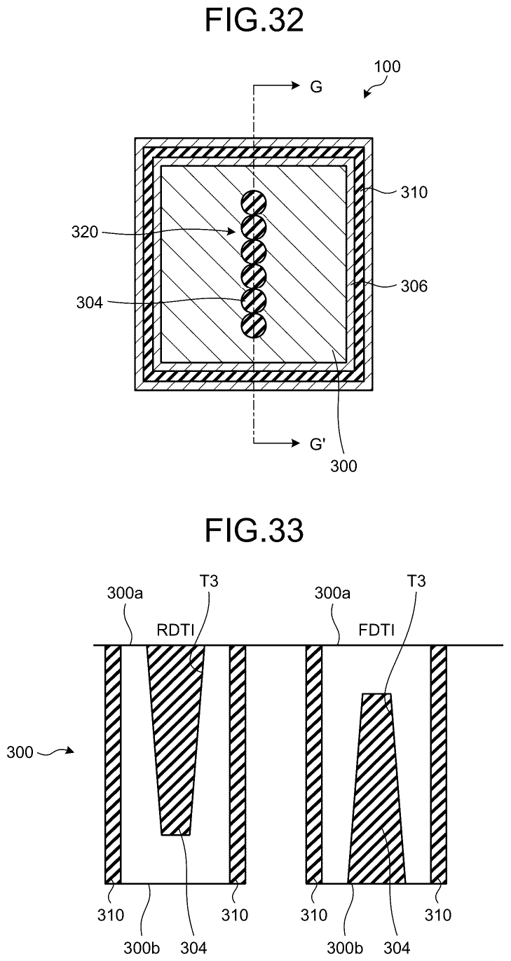

Note that although the configuration of the pixel isolation portion 304 has been described in the embodiments of the present disclosure described above, a configuration according to an embodiment of the present disclosure is not limited thereto. Here, various aspects of a pixel isolation portion 304 will be described with reference to FIG. 32 and FIG. 33.

FIG. 32 is an explanatory diagram illustrating a plane of an imaging element 100 according to the present embodiment (modification example), and specifically corresponds to a cross section of the imaging element 100 cut in a plane direction of a semiconductor substrate 300. FIG. 33 is an explanatory diagram illustrating a part of a cross section of the imaging element 100 of each structure, that is, the semiconductor substrate 300 of each structure according to the present embodiment (modification example), and specifically corresponds to a cross section obtained by cutting of the semiconductor substrate 300 of each structure along a line G-G′ illustrated in FIG. 32. Note that although not illustrated in FIG. 33, a surface of the pixel isolation portion 304 is assumed to have an uneven shape.

As illustrated in FIG. 33, the pixel isolation portion 304 can have either form of rear DTI (RDTI) or front DTI (FDTI). In these forms, a trench T3 is formed in a thickness direction of the semiconductor substrate 300. A high refractive material is embedded in the trench T3. Note that although the trench T3 is formed in a tapered shape expanding from a surface of the semiconductor substrate 300 toward the inside in the example of FIG. 33, this is not a limitation. For example, the trench T3 may be formed straight in such a manner as to be orthogonal (or substantially orthogonal) to the surface of the semiconductor substrate 300.

The RDTI is a structure in which a trench T3 is formed from a light receiving surface 300a of the semiconductor substrate 300 to a middle of the semiconductor substrate 300. The FDTI is a structure in which a trench is formed from a surface 300b of the semiconductor substrate 300 to the middle of the semiconductor substrate 300.

### <8. Application Example

### 8.1 Example of Application to a Camera

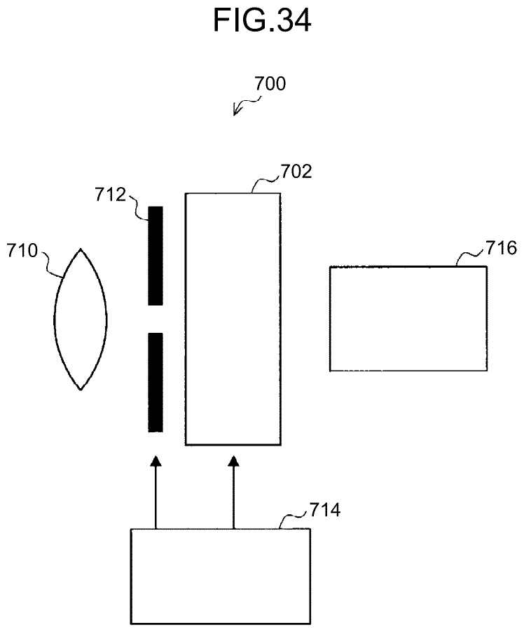

A technology according to the present disclosure (present technology) can be applied to various products. For example, the technology according to the present disclosure may be applied to a camera or the like. Thus, a configuration example of a camera 700 as an electronic device to which the present technology is applied will be described with reference to FIG. 34. FIG. 34 is an explanatory diagram illustrating an example of a schematic functional configuration of a camera 700 to which the technology according to the present disclosure (present technology) can be applied.

As illustrated in FIG. 34, the camera 700 includes an imaging device 702, an optical lens 710, a shutter mechanism 712, a driving circuit unit 714, and a signal processing circuit unit 716. The optical lens 710 forms an image of image light (incident light) from a subject on an imaging surface of the imaging device 702. As a result, signal charge is accumulated in an imaging element 100 of the imaging device 702 for a certain period of time. The shutter mechanism 712 opens and closes to control a light emission period and a light shielding period for the imaging device 702. The driving circuit unit 714 supplies a drive signal for controlling a signal transfer operation of the imaging device 702, a shutter operation of the shutter mechanism 712, and the like to these device and mechanism. That is, the imaging device 702 performs signal transfer on the basis of the drive signal (timing signal) supplied from the driving circuit unit 714. The signal processing circuit unit 716 performs various types of signal processing. For example, the signal processing circuit unit 716 outputs a video signal subjected to the signal processing to, for example, a storage medium (not illustrated) such as a memory, or to a display unit (not illustrated).

As described above, the imaging element 100 according to the embodiment of the present disclosure can be applied to the imaging device 702 of the camera 700.

### 8.2 Example of Application to a Smartphone

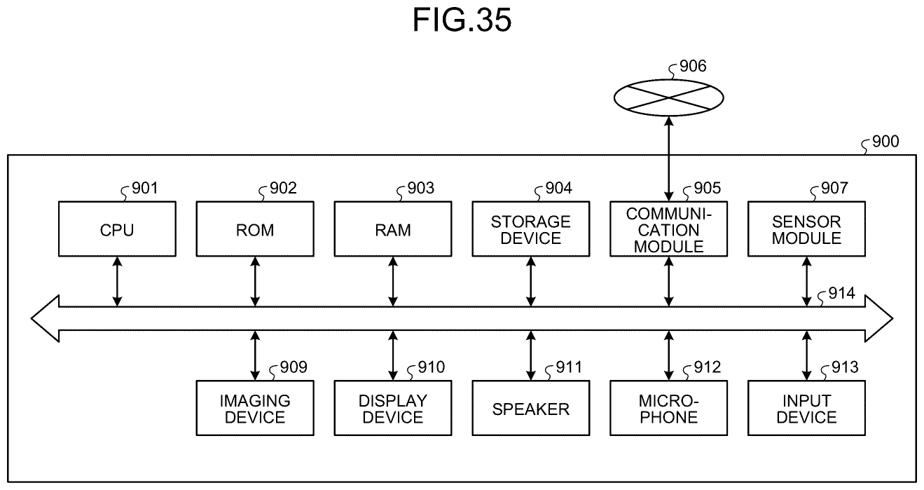

The technology according to the present disclosure (present technology) can be further applied to various products. For example, the technology according to the present disclosure may be applied to a smartphone or the like. Thus, a configuration example of a smartphone 900 as an electronic device to which the present technology is applied will be described with reference to FIG. 35. FIG. 35 is a block diagram illustrating an example of a schematic functional configuration of the smartphone 900 to which the technology according to the present disclosure (the present technology) can be applied.

As illustrated in FIG. 35, the smartphone 900 includes a central processing unit (CPU) 901, a read only memory (ROM) 902, and a random access memory (RAM) 903. In addition, the smartphone 900 includes a storage device 904, a communication module 905, and a sensor module 907. Furthermore, the smartphone 900 includes an imaging device 909, a display device 910, a speaker 911, a microphone 912, an input device 913, and a bus 914. Furthermore, the smartphone 900 may include a processing circuit such as a digital signal processor (DSP) instead of or in addition to the CPU 901.

The CPU 901 functions as an arithmetic processing device and a control device, and controls an overall operation in the smartphone 900 or a part thereof according to various programs recorded in the ROM 902, the RAM 903, the storage device 904, or the like. The ROM 902 stores the programs used by the CPU 901, operation parameters, and the like. The RAM 903 performs primary storing of the programs used in execution of the CPU 901, the parameters that appropriately change in the execution, and the like. The CPU 901, the ROM 902, and the RAM 903 are connected to each other by the bus 914. In addition, the storage device 904 is a device for data storage which device is configured as an example of a storage unit of the smartphone 900. The storage device 904 includes, for example, a magnetic storage device such as a hard disk drive (HDD), a semiconductor storage device, an optical storage device, or the like. The storage device 904 stores the programs executed by the CPU 901, various kinds of data, various kinds of data obtained from the outside, and the like.

The communication module 905 is, for example, a communication interface including a communication device or the like for connection to a communication network 906. The communication module 905 may be, for example, a communication card for a wired or wireless local area network (LAN), Bluetooth (registered trademark), a wireless USB (WUSB), or the like. Furthermore, the communication module 905 may be a router for optical communication, a router for an asymmetric digital subscriber line (ADSL), a modem for various kinds of communication, or the like. The communication module 905 transmits and receives a signal or the like to and from the Internet or another communication device by using a predetermined protocol such as a transmission control protocol (TCP)/Internet protocol (IP). Furthermore, the communication network 906 connected to the communication module 905 is a network connected in a wired or wireless manner, and is, for example, the Internet, a home LAN, infrared communication, satellite communication, or the like.

The sensor module 907 includes, for example, various sensors such as a motion sensor (such as an acceleration sensor, a gyroscope sensor a geomagnetic sensor, or the like), a biological information sensor (such as a pulse sensor, a blood pressure sensor, a fingerprint sensor, or the like), or a position sensor (such as a global navigation satellite system (GNSS) receiver or the like).

The imaging device 909 is provided on a surface of the smartphone 900, and can image an object or the like located on a back side or a front side of the smartphone 900. Specifically, the imaging device 909 can include an imaging element 100 such as a complementary MOS (CMOS) image sensor to which the technology according to the present disclosure (present technology) can be applied, and a signal processing circuit (not illustrated) that performs imaging signal processing on a signal photoelectrically converted by the imaging element. Furthermore, the imaging device 909 can further include an optical system mechanism (not illustrated) including an imaging lens, a zoom lens, a focus lens, and the like, and a driving system mechanism (not illustrated) that controls an operation of the optical system mechanism. Then, the imaging element collects incident light from the object as an optical image, and the signal processing circuit can obtain a captured image by photoelectrically converting the formed optical image in units of pixels, reading a signal of each pixel as an imaging signal, and performing image processing.

The display device 910 is provided on a surface of the smartphone 900, and can be, for example, a display device such as a liquid crystal display (LCD) or an organic electro luminescence (EL) display. The display device 910 can display an operation screen, the captured image obtained by the above-described imaging device 909, and the like.

The speaker 911 can output, for example, a call voice, a voice accompanying video content displayed by the display device 910 described above, and the like to a user.

The microphone 912 can collect, for example, a call voice of a user, a voice including a command to activate a function of the smartphone 900, and sound in a surrounding environment of the smartphone 900.

The input device 913 is a device operated by the user, such as a button, a keyboard, a touch panel, or a mouse. The input device 913 includes an input control circuit that generates an input signal on the basis of information input by the user and performs an output thereof to the CPU 901. By operating the input device 913, the user can input various kinds of data to the smartphone 900 and give an instruction on a processing operation.

The configuration example of the smartphone 900 has been described above. Each of the above-described components may be configured by utilization of a general-purpose member, or may be configured by hardware specialized for a function of each component. Such a configuration can be appropriately changed according to a technical level at the time of implementation.

### 9. Supplementary Note

Preferred embodiments of the present disclosure have been described in detail in the above with reference to the accompanying drawings. However, a technical scope of the present disclosure is not limited to such examples. It is obvious that a person having ordinary knowledge in the technical field of the present disclosure can conceive various alterations or modifications within the scope of the technical idea described in claims, and it should be understood that these alterations or modifications naturally belong to the technical scope of the present disclosure.

In addition, the effects described in the present specification are merely illustrative or exemplary, and are not restrictive. That is, in addition to the above effects or instead of the above effects, the technology according to the present disclosure can exhibit a different effect obvious to those skilled in the art from the description of the present specification.

Note that the present technology can also have the following configurations.

(1) An imaging device comprising:
a semiconductor substrate; and
a plurality of imaging elements that is arrayed in a matrix on the semiconductor substrate and that performs photoelectric conversion on incident light, wherein
each of the plurality of imaging elements includes
a plurality of pixels which is provided in such a manner as to be adjacent to each other in a predetermined unit region of the semiconductor substrate and each of which includes a photoelectric conversion unit, and
a pixel isolation portion that isolates the plurality of pixels,
the pixel isolation portion is provided in such a manner as to penetrate at least a part of the semiconductor substrate in a thickness direction of the semiconductor substrate, and
at least one of surfaces of the pixel isolation portion is an uneven surface.

(2) The imaging device according to (1), wherein the pixel isolation portion is made of a high refractive index material.

(3) The imaging device according to (1) or (2), wherein the uneven surface has a hemispherical, conical, or pyramidal protrusion.

(4) The imaging device according to any one of (1) to (3), wherein at least a part of a side surface of the pixel isolation portion is the uneven surface.

(5) The imaging device according to any one of (1) to (4), wherein
the plurality of imaging elements includes
a first imaging element that performs photoelectric conversion on light having a wavelength in a first wavelength band, and
a second imaging element that performs photoelectric conversion on light having a wavelength in a second wavelength band shorter than the first wavelength band.

(6) The imaging device according to (5), wherein a period of unevenness of the surface of the pixel isolation portion of the first imaging element is longer than a period of unevenness of the surface of the pixel isolation portion of the second imaging element.

(7) The imaging device according to (5), wherein a period of unevenness of the surface of the pixel isolation portion of the first imaging element is substantially same as a period of unevenness of the surface of the pixel isolation portion of the second imaging element.

(8) The imaging device according to any one of (5) to (7), wherein each of the plurality of imaging elements further includes an on-chip lens provided above a light receiving surface of the semiconductor substrate in such a manner as to be shared by the plurality of pixels.

(9) The imaging device according to (8), wherein the pixel isolation portion is provided in such a manner as to penetrate the part of the semiconductor substrate in the thickness direction of the semiconductor substrate from a surface facing the light receiving surface.

(10) The imaging device according to (9), wherein an upper surface of the pixel isolation portion which surface is located on a side of the light receiving surface is an uneven surface.

(11) The imaging device according to (9) or (10), wherein a length of the pixel isolation portion of the first imaging element in the thickness direction of the semiconductor substrate is longer than a length of the pixel isolation portion of the second imaging element in the thickness direction of the semiconductor substrate.

(12) The imaging device according to (9) or (10), wherein a length of the pixel isolation portion of the first imaging element in the thickness direction of the semiconductor substrate is shorter than a length of the pixel isolation portion of the second imaging element in the thickness direction of the semiconductor substrate.

(13) The imaging device according to (9) or (10), wherein a length of the pixel isolation portion of the first imaging element in the thickness direction of the semiconductor substrate is substantially same as a length of the pixel isolation portion of the second imaging element in the thickness direction of the semiconductor substrate.

(14) The imaging device according to (8), wherein
the pixel isolation portion includes
a first isolation portion provided in such a manner as to penetrate a part of the semiconductor substrate in the thickness direction of the semiconductor substrate from a surface facing the light receiving surface, and
a second isolation portion provided in such a manner as to penetrate a part of the semiconductor substrate in the thickness direction of the semiconductor substrate from the first isolation portion toward the light receiving surface,
a side surface of the first isolation portion is flat, and
a side surface of the second isolation portion is the uneven surface.

(15) The imaging device according to (14), wherein a length of the first isolation portion of the pixel isolation portion of the first imaging element in the thickness direction of the semiconductor substrate is substantially same as a length of the first isolation portion of the pixel isolation portion of the second imaging element in the thickness direction of the semiconductor substrate.

(16) The imaging device according to (8), wherein the pixel isolation portion is provided in such a manner as to penetrate the part of the semiconductor substrate from the light receiving surface in the thickness direction of the semiconductor substrate.

(17) The imaging device according to (8), wherein
the pixel isolation portion includes
a first isolation portion provided in such a manner as to penetrate a part of the semiconductor substrate from the light receiving surface in the thickness direction of the semiconductor substrate, and
a second isolation portion provided in such a manner as to penetrate a part of the semiconductor substrate from a surface facing the light receiving surface.

(18) The imaging device according to any one of (1) to (17), wherein
each of the plurality of imaging elements includes two of the pixels.

(19) The imaging device according to any one of (1) to (18), wherein
each of the plurality of imaging elements includes
an element isolation wall surrounding the predetermined unit region of the semiconductor substrate and penetrating the semiconductor substrate in the thickness direction of the semiconductor substrate.

(20) An electronic device comprising:
an imaging device including
a semiconductor substrate, and
a plurality of imaging elements that is arrayed in a matrix on the semiconductor substrate and that performs photoelectric conversion on incident light, wherein
each of the plurality of imaging elements includes
a plurality of pixels which is provided in such a manner as to be adjacent to each other in a predetermined unit region of the semiconductor substrate and each of which includes a photoelectric conversion unit, and
a pixel isolation portion that isolates the plurality of pixels,
the pixel isolation portion is provided in such a manner as to penetrate at least a part of the semiconductor substrate in a thickness direction of the semiconductor substrate, and
at least one of surfaces of the pixel isolation portion is an uneven surface.

### REFERENCE SIGNS LIST

1, 702, 909 IMAGING DEVICE
20 PIXEL ARRAY UNIT
21 VERTICAL DRIVING CIRCUIT PORTION
22 COLUMN SIGNAL PROCESSING CIRCUIT PORTION
23 HORIZONTAL DRIVING CIRCUIT PORTION
24 OUTPUT CIRCUIT PORTION
25 CONTROL CIRCUIT PORTION
26 PIXEL DRIVING WIRING LINE
27 VERTICAL SIGNAL LINE
28 HORIZONTAL SIGNAL LINE
29 INPUT/OUTPUT TERMINAL
100, 100a, 100B, 100G, 100R IMAGING ELEMENT
200 ON-CHIP LENS
202 COLOR FILTER
204 LIGHT SHIELDING PORTION
300 SEMICONDUCTOR SUBSTRATE
300a LIGHT RECEIVING SURFACE
300b SURFACE
302a, 302b PIXEL
304 PIXEL ISOLATION PORTION
304a, 304b ISOLATION PORTION
306 DIFFUSION REGION
310 ELEMENT ISOLATION WALL
320 UNEVENNESS
330 PROTRUSION
400 TRANSFER GATE
402 WIRING LAYER
500 MASK
700 CAMERA
710 OPTICAL LENS
712 SHUTTER MECHANISM
714 DRIVING CIRCUIT UNIT
716 SIGNAL PROCESSING CIRCUIT UNIT
900 SMARTPHONE
901 CPU
902 ROM
903 RAM
904 STORAGE DEVICE
905 COMMUNICATION MODULE
906 COMMUNICATION NETWORK
907 SENSOR MODULE
910 DISPLAY DEVICE
911 SPEAKER
912 MICROPHONE
913 INPUT DEVICE
914 BUS

1. An imaging device comprising:
a semiconductor substrate; and
a plurality of imaging elements that is arrayed in a matrix on the semiconductor substrate and that performs photoelectric conversion on incident light, wherein
each of the plurality of imaging elements includes
a plurality of pixels which is provided in such a manner as to be adjacent to each other in a predetermined unit region of the semiconductor substrate and each of which includes a photoelectric conversion unit, and
a pixel isolation portion that isolates the plurality of pixels,
the pixel isolation portion is provided in such a manner as to penetrate at least a part of the semiconductor substrate in a thickness direction of the semiconductor substrate, and
at least one of surfaces of the pixel isolation portion is an uneven surface.

2. The imaging device according to claim 1, wherein the pixel isolation portion is made of a high refractive index material.

3. The imaging device according to claim 1, wherein the uneven surface has a hemispherical, conical, or pyramidal protrusion.

4. The imaging device according to claim 1, wherein at least a part of a side surface of the pixel isolation portion is the uneven surface.

5. The imaging device according to claim 1, wherein
the plurality of imaging elements includes
a first imaging element that performs photoelectric conversion on light having a wavelength in a first wavelength band, and
a second imaging element that performs photoelectric conversion on light having a wavelength in a second wavelength band shorter than the first wavelength band.

6. The imaging device according to claim 5, wherein a period of unevenness of the surface of the pixel isolation portion of the first imaging element is longer than a period of unevenness of the surface of the pixel isolation portion of the second imaging element.

7. The imaging device according to claim 5, wherein a period of unevenness of the surface of the pixel isolation portion of the first imaging element is substantially same as a period of unevenness of the surface of the pixel isolation portion of the second imaging element.

8. The imaging device according to claim 5, wherein each of the plurality of imaging elements further includes an on-chip lens provided above a light receiving surface of the semiconductor substrate in such a manner as to be shared by the plurality of pixels.

9. The imaging device according to claim 8, wherein the pixel isolation portion is provided in such a manner as to penetrate the part of the semiconductor substrate in the thickness direction of the semiconductor substrate from a surface facing the light receiving surface.

10. The imaging device according to claim 9, wherein an upper surface of the pixel isolation portion which surface is located on a side of the light receiving surface is an uneven surface.

11. The imaging device according to claim 9, wherein a length of the pixel isolation portion of the first imaging element in the thickness direction of the semiconductor substrate is longer than a length of the pixel isolation portion of the second imaging element in the thickness direction of the semiconductor substrate.

12. The imaging device according to claim 9, wherein a length of the pixel isolation portion of the first imaging element in the thickness direction of the semiconductor substrate is shorter than a length of the pixel isolation portion of the second imaging element in the thickness direction of the semiconductor substrate.

13. The imaging device according to claim 9, wherein a length of the pixel isolation portion of the first imaging element in the thickness direction of the semiconductor substrate is substantially same as a length of the pixel isolation portion of the second imaging element in the thickness direction of the semiconductor substrate.

14. The imaging device according to claim 8, wherein
the pixel isolation portion includes
a first isolation portion provided in such a manner as to penetrate a part of the semiconductor substrate in the thickness direction of the semiconductor substrate from a surface facing the light receiving surface, and
a second isolation portion provided in such a manner as to penetrate a part of the semiconductor substrate in the thickness direction of the semiconductor substrate from the first isolation portion toward the light receiving surface,
a side surface of the first isolation portion is flat, and
a side surface of the second isolation portion is the uneven surface.

15. The imaging device according to claim 14, wherein a length of the first isolation portion of the pixel isolation portion of the first imaging element in the thickness direction of the semiconductor substrate is substantially same as a length of the first isolation portion of the pixel isolation portion of the second imaging element in the thickness direction of the semiconductor substrate.

16. The imaging device according to claim 8, wherein the pixel isolation portion is provided in such a manner as to penetrate the part of the semiconductor substrate from the light receiving surface in the thickness direction of the semiconductor substrate.

17. The imaging device according to claim 8, wherein
the pixel isolation portion includes
a first isolation portion provided in such a manner as to penetrate a part of the semiconductor substrate from the light receiving surface in the thickness direction of the semiconductor substrate, and
a second isolation portion provided in such a manner as to penetrate a part of the semiconductor substrate from a surface facing the light receiving surface.

18. The imaging device according to claim 1, wherein
each of the plurality of imaging elements includes two of the pixels.

19. The imaging device according to claim 1, wherein
each of the plurality of imaging elements includes
an element isolation wall surrounding the predetermined unit region of the semiconductor substrate and penetrating the semiconductor substrate in the thickness direction of the semiconductor substrate.

20. An electronic device comprising:
an imaging device including
a semiconductor substrate, and
a plurality of imaging elements that is arrayed in a matrix on the semiconductor substrate and that performs photoelectric conversion on incident light, wherein
each of the plurality of imaging elements includes
a plurality of pixels which is provided in such a manner as to be adjacent to each other in a predetermined unit region of the semiconductor substrate and each of which includes a photoelectric conversion unit, and
a pixel isolation portion that isolates the plurality of pixels,
the pixel isolation portion is provided in such a manner as to penetrate at least a part of the semiconductor substrate in a thickness direction of the semiconductor substrate, and
at least one of surfaces of the pixel isolation portion is an uneven surface.
